(19) United States
(12) Patent Application Publication
(10) Pub. No.: US 2018/0145242 A1
(43) Pub. Date: May 24, 2018

(54) POWER SUPPLY CIRCUIT AND AC ADAPTOR

(71) Applicant: Murata Manufacturing Co., Ltd., Nagaokakyo-shi (JP)

(72) Inventors: TAKEAKI TAMAYAMA, Nagaokakyo-shi (JP); Tatsuya Ito, Nagaokakyo-shi (JP)

(21) Appl. No.: 15/873,223

(22) Filed: Jan. 17, 2018

Related U.S. Application Data
(63) Continuation of application No. PCT/JP2016/071486, filed on Jul. 22, 2016.

(30) Foreign Application Priority Data
Jul. 28, 2015 (JP) 2015-148222
Nov. 17, 2015 (JP) 2015-224798
Dec. 1, 2015 (JP) 2015-234574
Mar. 7, 2016 (JP) 2016-042940

(51) Int. Cl. H01L 41/04; H02M 7/12; H02M 7/5387; G05F 1/46; H01L 41/107; H01L 41/113; H02N 2/18

(52) U.S. Cl. CPC H01L 41/044; H02M 7/12; H02M 7/53871; H02N 2/181; H01L 41/107; H01L 41/113; G05F 1/46

(57) ABSTRACT

An AC adaptor is provided that includes a piezoelectric transformer, a switching circuit that is connected to an input electrode of the piezoelectric transformer and performs conversion of an input voltage by turning on and turning off switching elements. Moreover, a diode bridge and a smoothing capacitor are connected to output electrodes and a parallel circuit is connected between an input electrode and the switching circuit and includes a capacitor and a diode. In addition, a rectifying and smoothing circuit is connected in parallel with the parallel circuit and includes a diode and a capacitor. Accordingly, a power supply circuit and an AC adaptor are provided that generate an auxiliary power supply without hindering reduction in size.

### CROSS REFERENCE TO RELATED APPLICATIONS

The present application is a continuation of PCT/JP2016/071486 filed Jul. 22, 2016, which claims priority to Japanese Patent Application No. 2016-042940, filed Mar. 7, 2016, Japanese Patent Application No. 2015-234574, filed Dec. 1, 2015, Japanese Patent Application No. 2015-224798, filed Nov. 17, 2015, and Japanese Patent Application No. 2015-148222, filed Jul. 28, 2015, the entire contents of each of which are incorporated herein by reference.

### TECHNICAL FIELD

The present disclosure relates to a power supply circuit and an AC adaptor that use a piezoelectric transformer.

### BACKGROUND

In general, an insulation-type AC-DC converter circuit, for example, an AC adaptor, includes a switching element that performs switching of an input commercial power supply voltage and a driver that causes the switching element to operate. There is a large difference between the commercial power supply voltage and a driving voltage of the driver. Therefore, some AC adaptors include an auxiliary power supply for generating a driving voltage to be applied to a driver. Auxiliary power supplies are available that generate a driving voltage of a driver based on a voltage that is obtained, in a case where an AC adaptor includes a winding transformer, by separately providing an auxiliary winding at the winding transformer.

In recent years, there has been a demand for reducing the size of such devices. In such circumstances, in place of winding transformers, AC-DC converter circuits including a piezoelectric transformer have been suggested (see, for example, Patent Document 1, identified below). An AC-DC converter circuit described in Patent Document 1 includes a piezoelectric transformer, and therefore, the auxiliary winding mentioned above cannot be provided at the AC-DC converter circuit. Thus, an auxiliary winding is provided at a resonance inductor that is connected in series with the piezoelectric transformer. A magnetic flux generated by current flowing through the inductor is coupled to the auxiliary winding, and thereby obtain voltage.

Patent Document 1: Japanese Unexamined Patent Application Publication No. 2000-102246.

However, in the design of Patent Document 1, even though the use of a piezoelectric transformer may reduce the size of a transformer part, there is a problem in that provision of an auxiliary winding for an auxiliary power supply hinders reduction in size of the entire circuit.

### SUMMARY OF THE INVENTION

Thus, according to the present disclosure, a power supply circuit and an AC adaptor are provided that generate an auxiliary power supply without hindering reduction in size.

Thus, a power supply circuit is disclosed according to an exemplary embodiment that includes a piezoelectric transformer that includes a pair of voltage input electrodes and a pair of voltage output electrodes. Moreover, a switching circuit is provided that is connected to the pair of voltage input electrodes and converts an input voltage into an AC voltage by turning on and off a switching element. An output-side rectifying and smoothing circuit is provided that is connected to the pair of voltage output electrodes; a first reactance element is provided that is connected between the pair of voltage input electrodes and the switching circuit; and an auxiliary-power-supply-side rectifying and smoothing circuit is provided that is connected to the first reactance element.

By connecting the first reactance element in series or parallel with the piezoelectric transformer, an output voltage from the auxiliary-power-supply-side rectifying and smoothing circuit may be adjusted by the first reactance element. Accordingly, unlike convention technologies, there is no need to configure a winding transformer to generate an auxiliary power supply. Therefore, the size of the power supply circuit can be reduced as compared with such conventional devices.

In an exemplary aspect, the first reactance element may be an auxiliary power supply capacitor. The power supply circuit may further include a diode that is connected in parallel with the auxiliary power supply capacitor. The auxiliary-power-supply-side rectifying and smoothing circuit may be connected to a parallel circuit including the auxiliary power supply capacitor and the diode.

With this configuration, an output voltage from the auxiliary-power-supply-side rectifying and smoothing circuit may be adjusted by the auxiliary power supply capacitor. Accordingly, unlike convention technologies, there is no need to configure a winding transformer to generate an auxiliary power supply, and, therefore, the size of the power supply circuit can be reduced.

In one aspect, the auxiliary power supply capacitor may be connected to the pair of voltage input electrodes.

The piezoelectric transformer is a capacitive device. By connecting the auxiliary power supply capacitor to the piezoelectric transformer, it may be considered that a capacitance dividing circuit is connected to the switching circuit. Therefore, a voltage to be applied to the switching circuit may be divided and output from the auxiliary-power-supply-side rectifying and smoothing circuit. Accordingly, unlike convention technologies, there is no need to configure a winding transformer to generate an auxiliary power supply, and therefore, the size of the power supply circuit can be reduced.

In one aspect, a capacitance of the auxiliary power supply capacitor may be equal to or more than an input capacitance of the piezoelectric transformer.

With this configuration, by adjusting the input capacitance of the piezoelectric transformer, an output voltage from the auxiliary-power-supply-side rectifying and smoothing circuit may be adjusted.

Moreover, the auxiliary power supply capacitor may be connected in parallel with the pair of voltage input electrodes.

The power supply circuit may further include an inductor that is connected between the pair of voltage input electrodes and the switching circuit. The auxiliary power supply capacitor may be connected in parallel with a series circuit including the inductor and the pair of voltage input electrodes.

With this configuration, a situation in which a plurality of resonance points appear may be prevented.

In one aspect, the power supply circuit may further include a voltage dividing capacitor that is connected in series with the parallel circuit.

A capacitance of the voltage dividing capacitor may be less than or equal to the capacitance of the auxiliary power supply capacitor.

With this configuration, regarding the impedance of the series circuit including the voltage dividing capacitor and the parallel circuit, the voltage dividing capacitor is predominant. Therefore, a voltage to be applied to the series circuit may be determined by the voltage dividing capacitor.

The parallel circuit may be a circuit in which a series circuit including a plurality of auxiliary power supply capacitors and the diode are connected in parallel.

The auxiliary-power-supply-side rectifying and smoothing circuit may include a plurality of auxiliary-power supply-side rectifying and smoothing circuits. At least one of the auxiliary-power-supply-side rectifying and smoothing circuits may be connected to a connection point of the plurality of auxiliary power supply capacitors.

With this configuration, voltages of different voltage values may be output from the auxiliary-power-supply-side rectifying and smoothing circuit.

In one aspect, the power supply circuit may further include a second reactance element that is connected in parallel with the series circuit including the plurality of auxiliary power supply capacitors.

Moreover, the power supply circuit may further include an inductive circuit that includes the first reactance element and becomes inductive at a switching frequency of the switching circuit. The auxiliary-power-supply-side rectifying and smoothing circuit may be connected to the inductive circuit.

The piezoelectric transformer is a capacitive device. That is, with this configuration, it may be considered that a capacitive element and an inductive element are connected in series with the switching circuit. When a voltage is applied from the switching circuit to the piezoelectric transformer, a voltage applied to the inductive circuit may be obtained from a connection point of the piezoelectric transformer and the inductive circuit. Regarding the series circuit including the capacitive element and the inductive element, by increasing the inductance of the inductive element, the voltage applied to the inductive element is increased, and a greater voltage may thus be obtained. The power supply circuit may use such a voltage as an auxiliary power supply. Accordingly, unlike convention technologies, there is no need to configure a winding transformer to generate an auxiliary power supply, and, therefore, the size of the power supply circuit can be reduced.

The first reactance element may be an inductor. The inductive circuit may be configured such that the inductor and a capacitor are connected in parallel.

With this configuration, by using resonance of the inductor and the capacitor, noise of a voltage obtained from the connection point of the piezoelectric transformer and the inductive circuit may be reduced. Furthermore, by varying the capacitance of the capacitor, an obtained voltage may be adjusted.

The inductive circuit may include a series connection unit in which a plurality of inductors are connected in series.

The auxiliary-power-supply-side rectifying and smoothing circuit may include a plurality of auxiliary-power supply-side rectifying and smoothing circuits. At least one of the plurality of auxiliary-power-supply-side rectifying and smoothing circuits may be connected to a connection point of two inductors.

With this configuration, different voltages may be extracted.

In addition, the power supply circuit may further include a capacitor that is connected in parallel with the series connection unit.

The power supply circuit may further include an inductor that is connected in parallel with the series connection unit.

In one aspect, the first reactance element may be an inductor. The inductive circuit may be configured such that an inductor is connected in parallel with the inductor and a capacitor that are connected in series. The auxiliary-power-supply-side rectifying and smoothing circuit may include a plurality of auxiliary-power supply-side rectifying and smoothing circuits. At least one of the plurality of auxiliary-power-supply-side rectifying and smoothing circuits may be connected to a connection point of the capacitor and the inductor that are connected in series.

With this configuration, different voltages may be extracted.

The first reactance element and the switching circuit may be connected via ground.

With this configuration, a simplified circuit configuration may be achieved.

The power supply circuit may further include a voltage regulator that is connected to the auxiliary-power-supply-side rectifying and smoothing circuit.

With this configuration, constant voltage output may be achieved.

The power supply circuit may further include a driver circuit that is connected to the voltage regulator and drives the switching element.

With this configuration, an auxiliary power supply voltage may be generated without increasing the size of the circuit, and the driver circuit may be driven using the generated voltage.

The power supply circuit may further include a controller circuit that is connected to the voltage regulator and controls the switching element.

With this configuration, an auxiliary power supply voltage may be generated without increasing the size of the circuit, and the controller circuit may be driven using the generated voltage.

The power supply circuit may further include a detection circuit that detects a value based on an input current or input voltage input to the piezoelectric transformer; a circuit constant variable circuit that is connected to the pair of input electrodes or connected between the pair of input electrodes and the switching circuit and is able to change a circuit constant; and a changing unit (e.g., a controller) that changes the circuit constant of the circuit constant variable circuit according to the value detected by the detection circuit. The circuit constant variable circuit may include the first reactance element. The auxiliary-power-supply-side rectifying and smoothing circuit may rectify and smooth a voltage applied to the circuit constant variable circuit and outputs an auxiliary power supply voltage.

With this configuration, a voltage division circuit can be provided in which the capacitive element and the circuit constant variable circuit are connected in series with the switching circuit. When a voltage is applied to the piezoelectric transformer from the switching circuit, the applied voltage may be extracted by the voltage division circuit. When the weight of a load connected to the power supply circuit varies, ripples occurs in the input voltage to the switching circuit. Influence of the ripples may cause an output voltage from the auxiliary-power-supply-side rectifying and smoothing circuit to be varied. However, by causing the voltage dividing ratio of the voltage division circuit according to voltage variations by changing the circuit constant variable circuit by the detected input current or input voltage, voltage extracted from the voltage division circuit may be stabilized. Accordingly, a stable auxiliary power supply voltage may be output from the auxiliary-power-supply-side rectifying and smoothing circuit.

The circuit constant variable circuit may include a circuit constant fixing circuit.

With this configuration, detailed adjustment of the voltage dividing ratio may be easily performed, and extracted voltage may be adjusted in a detailed manner.

The circuit constant variable circuit may include a switching element. The changing unit may change the circuit constant of the circuit constant variable circuit by turning on and turning off the switching element.

With this configuration, the circuit constant variable circuit may have a simplified configuration.

The circuit constant variable circuit may include a variable capacitance element.

With this configuration, compared to the case where switching between switching elements is performed, high-frequency noise occurring at the time of switching may be reduced.

The detection circuit may be connected to an input side of the switching circuit.

With this configuration, a current voltage input to the switching circuit is a direct current, and therefore, the input voltage or input current may be detected with high accuracy.

An AC adaptor according to an exemplary aspect includes an input unit that is connected to a commercial power supply and inputs a voltage from the commercial power supply. Moreover, an input-side rectifying and smoothing circuit is included that rectifies and smooths the voltage input from the input unit; a piezoelectric transformer is provided that includes a pair of voltage input electrodes and a pair of voltage output electrodes; a switching circuit is included that is connected to the pair of voltage input electrodes and performs conversion of the voltage rectified and smoothed by the input-side rectifying and smoothing circuit by turning on and turning off the switching element; an output-side rectifying and smoothing circuit is provided that is connected to the pair of voltage output electrodes; an output unit is provided that outputs the voltage rectified and smoothed by the output-side rectifying and smoothing circuit; a reactance element is provided that is connected between the pair of voltage input electrodes and the switching circuit; and an auxiliary-power-supply-side rectifying and smoothing circuit is provided that is connected to the reactance element.

According to the present disclosure, unlike conventional technologies, without requiring a winding transformer to be configured, a power supply circuit and an AC adaptor are provided that generate an auxiliary power supply without hindering reduction in size of the power supply circuit.

### BRIEF DESCRIPTION OF DRAWINGS

FIG. 1 is a circuit diagram of an AC adaptor according to an exemplary embodiment.

FIG. 2 is a circuit diagram of an AC adaptor in which a piezoelectric transformer illustrated in FIG. 1 is represented by an equivalent circuit.

FIG. 3 is a waveform chart of a voltage Vdiv at a connection point A1.

FIG. 4 is a circuit diagram of an AC adaptor according to a second exemplary embodiment.

FIG. 5 is a circuit diagram of an AC adaptor according to a third exemplary embodiment.

FIG. 6 is a circuit diagram of an AC adaptor according to a fourth exemplary embodiment.

FIG. 7 is a circuit diagram of another example of the AC adaptor according to the fourth exemplary embodiment.

FIG. 8 is a circuit diagram of an AC adaptor according to a fifth exemplary embodiment.

FIG. 9 is a circuit diagram of an AC adaptor according to a sixth exemplary embodiment.

FIG. 10 is a circuit diagram of an AC adaptor according to a seventh exemplary embodiment.

FIG. 11 is a circuit diagram of an AC adaptor in which a piezoelectric transformer illustrated in FIG. 10 is represented by an equivalent circuit.

FIG. 12 is a diagram illustrating a voltage waveform at a connection point of a piezoelectric transformer and an inductor.

FIG. 13 is a diagram illustrating an output voltage waveform of a rectifying and smoothing circuit.

FIG. 14 is a circuit diagram of an AC adaptor according to an eighth exemplary embodiment.

FIG. 15 is a diagram illustrating a voltage waveform at a connection point of a piezoelectric transformer and an inductor.

FIG. 16 is a diagram illustrating an output voltage waveform of a rectifying and smoothing circuit.

FIG. 17 is a circuit diagram of an AC adaptor according to a ninth exemplary embodiment.

FIG. 18 is a circuit diagram of an AC adaptor according to a tenth exemplary embodiment.

FIG. 19 is a circuit diagram of an auxiliary power supply circuit according to an exemplary embodiment.

FIG. 20 is a circuit diagram of an auxiliary power supply circuit according to an exemplary embodiment.

FIG. 21 is a circuit diagram of an auxiliary power supply circuit according to an exemplary embodiment.

FIG. 22 is a circuit diagram of another example of the auxiliary power supply circuit.

FIG. 23 is a circuit diagram of an AC adaptor according to an eleventh exemplary embodiment.

FIG. 24 is a circuit diagram of an AC adaptor in which a piezoelectric transformer illustrated in FIG. 23 is represented by an equivalent circuit.

FIG. 25 is a diagram illustrating part of an internal circuit of a controller.

FIG. 26 is a diagram illustrating a waveform of an input voltage input to a voltage regulator.

FIG. 27 is a diagram illustrating another example of a circuit for changing a circuit constant.

FIG. 28 is a circuit diagram illustrating an auxiliary power supply circuit included in an AC adaptor according to a twelfth exemplary embodiment.

FIG. 29 is a circuit diagram illustrating an auxiliary power supply circuit included in an AC adaptor according to the twelfth exemplary embodiment.

FIG. 30 is a circuit diagram illustrating an auxiliary power supply circuit included in an AC adaptor according to the twelfth exemplary embodiment.

FIG. 31 is a diagram illustrating another example of an auxiliary power supply circuit included in an AC adaptor according to a thirteenth exemplary embodiment.

FIG. 32 is a circuit diagram of an AC adaptor according to a fourteenth exemplary embodiment.

FIG. 33 is a circuit diagram of an AC adaptor according to a fifteenth exemplary embodiment.

### DETAILED DESCRIPTION OF EXEMPLARY EMBODIMENTS

### First Embodiment

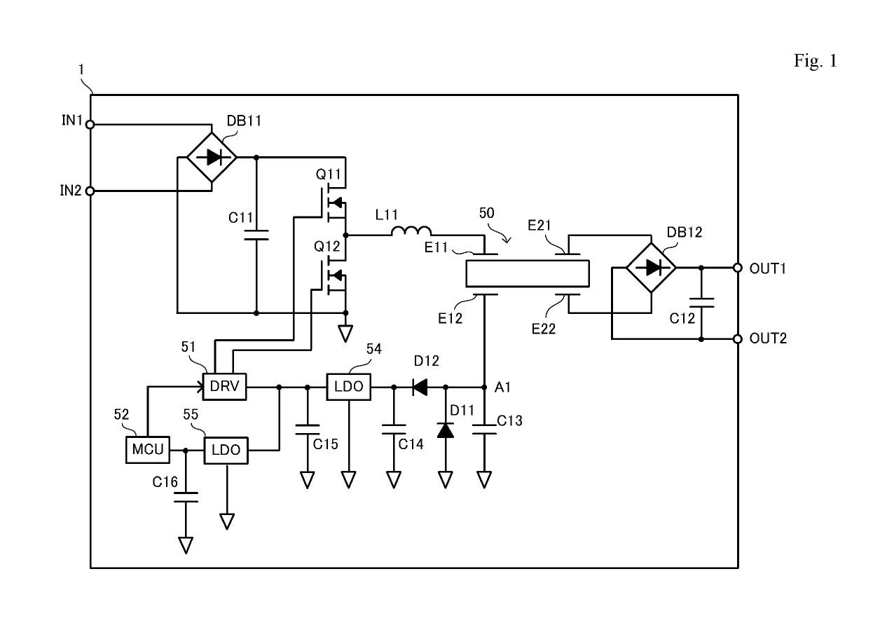

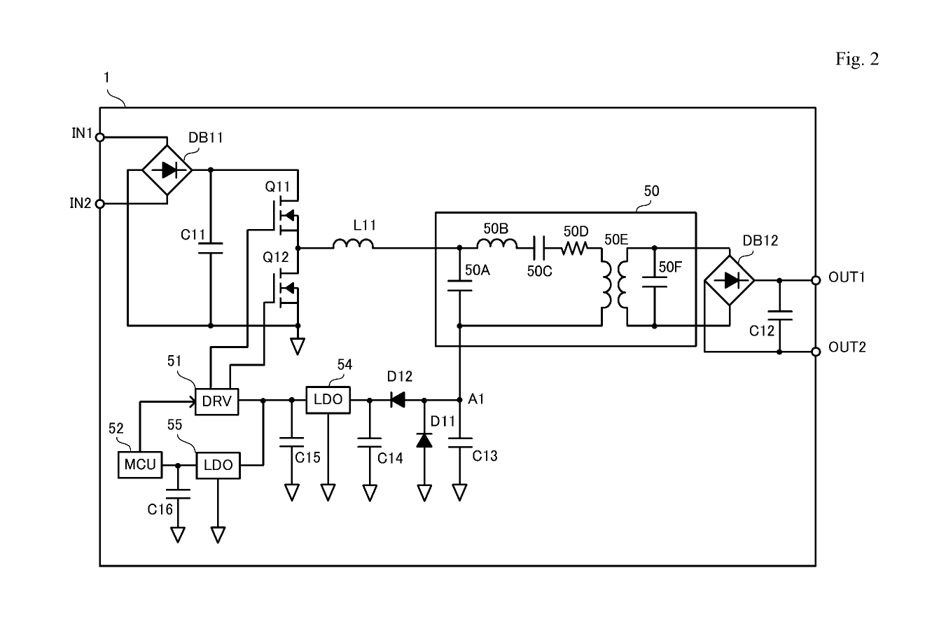

FIG. 1 is a circuit diagram of an AC adaptor 1 according to an exemplary embodiment. FIG. 2 is a circuit diagram of the AC adaptor 1 in which a piezoelectric transformer 50 illustrated in FIG. 1 is represented by an equivalent circuit.

As shown, the AC adaptor 1 includes input units IN1 and IN2 that are connected to a commercial power supply and input an AC voltage from the commercial power supply and output units OUT1 and OUT2 that are connected to loads and output a DC voltage to the loads. The AC adaptor 1 is an example of a “power supply circuit” according to the present disclosure.

A diode bridge DB11 is connected to the input units IN1 and IN2. A smoothing capacitor C11 is also connected to the diode bridge DB11. AC voltages input from the input units IN1 and IN2 are rectified and smoothed by the diode bridge DB11 and the smoothing capacitor C11. The diode bridge DB11 and the smoothing capacitor C11 are an example of an “input-side rectifying and smoothing circuit” according to the present disclosure.

Switching elements Q11 and Q12 that are connected in series are connected to the diode bridge DB11 and the smoothing capacitor C11. In FIGS. 1 and 2, the switching elements Q11 and Q12 are preferably MOS-FETs. However, the switching elements Q11 and Q12 may be IGBTs, bipolar transistors, or the like. The voltage that has been rectified and smoothed by the diode bridge DB11 and the like is converted into a voltage of a rectangular wave by switching of the switching elements Q11 and Q12. The switching elements Q11 and Q12 that are connected in series are an example of a “switching circuit” according to the present disclosure.

A driver (DRV) 51 is connected to gates of the switching elements Q11 and Q12. A microcomputer (MCU) 52 is connected to the driver 51. The microcomputer 52 detects, under feedback control, the weight of the loads connected to the output units OUT1 and OUT2, and sets switching frequencies of the switching elements Q11 and Q12 according to the detected weight. The driver 51 generates gate voltages in accordance with a control signal from the microcomputer 52, applies the gate voltages to the switching elements Q11 and Q12, and turns on and off the switching elements Q11 and Q12 at cycles set by the microcomputer 52. The driver 51 is an example of a “driver circuit” according to the present disclosure. The microcomputer 52 is an example of a “controller circuit” according to the present disclosure. In an exemplary aspect, the microcomputer 52 can include a processor or microprocessor with memory and software instructions stored thereon that are configured to execute the algorithms described herein when executed by the processor, as would be appreciated to one skilled in the art.

The piezoelectric transformer 50 is connected to a connection point of the switching elements Q11 and the switching element Q12. According to the exemplary aspect, the piezoelectric transformer 50 is of an insulation type, and includes input electrodes E11 and E12 and output electrodes E21 and E22. The input electrodes E11 and E12 are an example of a “pair of voltage input electrodes” according to the present disclosure. The output electrodes E21 and E22 are an example of a “pair of voltage output electrodes” according to the present disclosure.

The input electrode E11 of the piezoelectric transformer 50 is connected to the connection point of the switching elements Q11 and the switching element Q12 with an inductor L11 interposed therebetween. The input electrode E12 of the piezoelectric transformer 50 is connected to the source of the switching element Q12 via the ground. The input electrode E12 and the switching element Q12 are connected via the ground, thereby the circuit being simplified.

The output electrodes E21 and E22 of the piezoelectric transformer 50 are connected to a diode bridge DB12. A smoothing capacitor C12 is connected to the diode bridge DB12, and is also connected to the output units OUT1 and OUT2. The diode bridge DB12 and the smoothing capacitor C12 are an example of an “output-side rectifying and smoothing circuit” according to an exemplary aspect.

As illustrated in FIG. 2, the piezoelectric transformer 50 is equivalently represented by an equivalent input capacitor 50A, a capacitor 50C, an equivalent output capacitor 50F, an inductor 50B, a resistor 50D, and an ideal transformer 50E, for example. The inductor 50B, the capacitor 50C are parameters representing electromechanical coupling in this example.

In the exemplary aspect, a capacitor C13, which will be described below, is connected between the input electrode E12 of the piezoelectric transformer 50 and the ground. The equivalent input capacitor 50A of the piezoelectric transformer 50, together with the capacitor C13 and the inductor L11, forms a series resonance circuit. A voltage waveform is converted into a rectangular wave by the switching elements Q11 and Q12. However, with this series resonance circuit, a sine wave is always input to the piezoelectric transformer 50. The piezoelectric transformer 50 steps down the voltage input from the input electrodes E11 and E12 and causes the resultant voltage to be output from the output electrodes E21 and E22. The voltage which has been stepped down by the piezoelectric transformer 50 is rectified and smoothed by the diode bridge DB12 and the smoothing capacitor C12 and output from the output units OUT1 and OUT2.

An auxiliary power supply circuit is connected to the input electrode E12 of the piezoelectric transformer 50, as illustrated in FIG. 1. According to the exemplary aspect, driving voltages of the driver 51 and the microcomputer 52 are much lower than the voltage of the commercial power supply input to the AC adaptor 1. Therefore, the voltage of the commercial power supply cannot be used directly as the driving voltage of the driver 51 or the like. Thus, an auxiliary power supply circuit is provided separately, and a predetermined voltage is obtained based on the voltage applied to the piezoelectric transformer 50, so that the driving voltages of the driver 51 and the microcomputer 52 can be generated.

The auxiliary power supply circuit includes the capacitor C13, a diode D11, a diode D12 and a capacitor C14 that form a rectifying and smoothing circuit, voltage regulators (LDOs) 54 and 55, bypass capacitors C15 and C16, and the like.

In this aspect, one end of the capacitor C13 is connected to the input electrode E12 of the piezoelectric transformer 50, and the other end of the capacitor C13 is connected to the ground. A constant is set such that the capacitance of the capacitor C13 is equal to or more than the capacitance of the equivalent input capacitor 50A of the piezoelectric transformer 50. The capacitor C13 is an example of a “first reactance element” and an “auxiliary power supply capacitor” according to the present disclosure.

The piezoelectric transformer 50 is a capacitive device. With a configuration in which the capacitor C13 is connected in series with the piezoelectric transformer 50, it may be considered that the piezoelectric transformer 50 and the capacitor C13 form a capacitance dividing circuit. When voltage is applied to the piezoelectric transformer 50 from the switching elements Q11 and Q12, voltage applied to the capacitor C13 may be obtained from a connection point A1 of the piezoelectric transformer 50 and the capacitor C13.

The capacitance of the equivalent input capacitor 50A of the piezoelectric transformer 50 is set less than or equal to the capacitance of the capacitor C13. Therefore, a voltage applied to the series circuit including the equivalent input capacitor 50A and the capacitor C13 is determined mainly by the equivalent input capacitor 50A. Furthermore, the potential of the connection point A1 is adjusted by the capacitor C13.

The diode D11 is an element for causing a positive DC voltage to be output from the rectifying and smoothing circuit including the diode D12 and the capacitor C14.

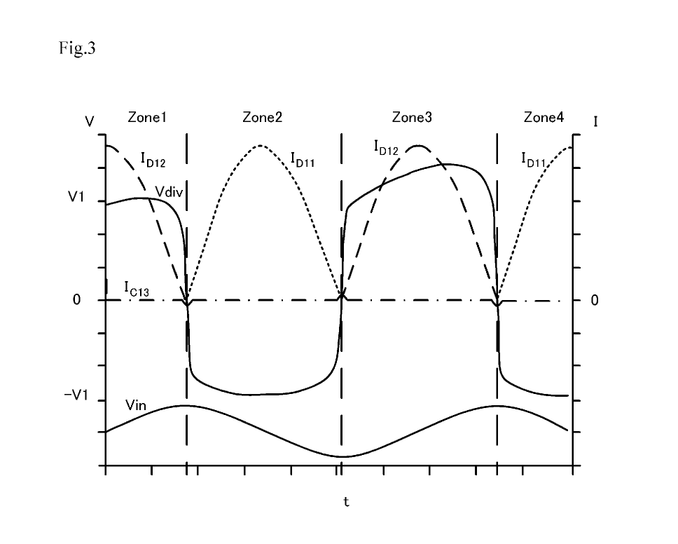

FIG. 3 is a waveform chart of a voltage Vdiv at the connection point A1. Waveforms of a voltage Vin applied to the piezoelectric transformer 50, currents I_{D11} and I_{D12} flowing in the diodes D11 and D12, and a current I_{C13} flowing in the capacitor C13 are also illustrated in FIG. 3. A horizontal axis in the chart represents time. Only a waveform is illustrated for the voltage Vin, and the scale on the vertical axis in the chart has no meaning for the voltage Vin. Furthermore, the same scale is used for the axes for the currents I_{D11}, I_{D12}, and I_{C13}.

[Zone 1]

During a period from rise to peak of the voltage Vin in which the voltage Vin is a positive voltage, the diode D12 is electrically connected and the current I_{D12} flowing in the diode D12 flows from the capacitor C14 to the ground. Therefore, the voltage at the connection point A1 is substantially equal to a forward drop voltage V1 of the diode D12. The current I_{D12} flowing in the diode D12 decreases immediately after the electrical connection, and reaches 0 mA at the peak of the voltage Vin.

[Zone 2 and Zone 4]

After the positive peak and the voltage Vin starts to drop, the direction of the current I_{C13} flowing in the capacitor C13 becomes negative (discharging direction), and the voltage Vdiv at the connection point A1 is thus lowered to the negative side. In the chart, the current I_{C13} is represented by a substantially straight line but slightly changes. At this time, the current I_{D11} flows in the forward direction of the diode D11. Therefore, the voltage at the connection point A1 drops only by an amount corresponding to a forward voltage (-V1) of the diode D11. Here, the current I_{D11} of the diode D11 and the current flowing in the equivalent input capacitor 50A are balanced to each other, and therefore, the current I_{D12} does not flow in the diode D12.

[Zone 3]

After the negative peak and the voltage Vin starts to increase, the direction of the current I_{C13} flowing in the capacitor C13 becomes positive (charging direction), and the voltage Vdiv at the connection point A1 is thus raised. The voltage Vdiv is the voltage across the capacitor C13. Therefore, when the current I_{C13} flowing in the capacitor C13 reaches 0 mA from the positive direction, the maximum current I_{C13} is obtained, and accordingly the maximum voltage Vdiv is obtained. Thus, the diode D12 is electrically connected. The current I_{D12} flowing in the diode D12 acts as a charging current of the capacitor C14, and the potential of the capacitor C14 thus increases at every cycle. Then, a positive DC voltage is output from the rectifying and smoothing circuit including the diode D12 and the capacitor C14.

Referring back to FIGS. 1 and 2, the diode D12 and the capacitor C14 are connected to the connection point A1. The diode D12 and the capacitor C14 rectify and smooth a voltage applied to the capacitor C13, and output a positive DC voltage, as explained above with reference to FIG. 3. The diode D12 and the capacitor C14 are an example of an “auxiliary-power-supply-side rectifying and smoothing circuit” according to the present disclosure.

As further shown, the voltage regulator 54 is connected to an output side of the diode D12 and the capacitor C14. The bypass capacitor C15 and the driver 51 are connected to an output side of the voltage regulator 54. The voltage regulator 54 converts a voltage output from the diode D12 and the capacitor C14 into a constant voltage necessary for the driver 51 in the subsequent stage. For example, in the case where a voltage of 18 V is output from the diode D12 and the capacitor C14 and a voltage necessary for driving the driver 51 is 12 V, the voltage regulator 54 steps down the input voltage of 18 V to a voltage of 12 V, and outputs the resultant voltage of 12 V. Accordingly, the driver 51 drives the gates of the switching elements Q11 and Q12.

The voltage regulator 55 is also connected to the output side of the voltage regulator 54. The bypass capacitor C16 and the microcomputer 52 are connected to an output side of the voltage regulator 55. During operation, the voltage regulator 55 converts a voltage output from the voltage regulator 54 into a voltage necessary for driving the microcomputer 52 in the subsequent stage. For example, in the case where a voltage necessary for operation of the microcomputer 52 is 3.3 V, the voltage regulator 55 steps down the voltage of 12 V, which has been converted and output by the voltage regulator 54, as described above, to a voltage of 3.3 V, and outputs the resultant voltage of 3.3 V. Accordingly, the microcomputer 52 operates.

As described above, with the provision of the voltage regulators 54 and 55, a constant voltage of a desired value based on an extracted voltage may be output.

The voltage regulators 54 and 55 are connected in cascade to generate the operating voltage of the microcomputer 52. With this configuration, decrease in the efficiency of the auxiliary power supply circuit may be prevented. That is, in the case where the voltage obtained from the connection point A1 is about 18 V and the driving voltage of the microcomputer 52 is 3.3 V, there is a large difference between the voltages. Therefore, when one voltage regulator performs conversion from 18 V to 3.3 V, there is a large loss in the auxiliary power supply circuit. Thus, in the case where the voltage regulator 54 performs conversion from 18 V to 12 V and the voltage regulator 55 then performs conversion from 12 V to 3.3 V, a loss in the auxiliary power supply circuit may be suppressed, and the efficiency may be increased.

As described above, the AC adaptor 1 according to this exemplary embodiment achieves reduction in size compared with conventional designs by using the piezoelectric transformer 50. In addition, an auxiliary power supply voltage may be generated by connecting the capacitor C13 to the piezoelectric transformer 50. Therefore, unlike conventional technologies, there is no need to configure a winding transformer, and, therefore, size of the AC adaptor 1 can be reduced. Furthermore, the capacitor C13, together with the equivalent input capacitor 50A of the piezoelectric transformer 50 and the inductor L11, forms a resonance circuit. Therefore, a situation in which a plurality of resonance points appear may be prevented.

### Second Embodiment

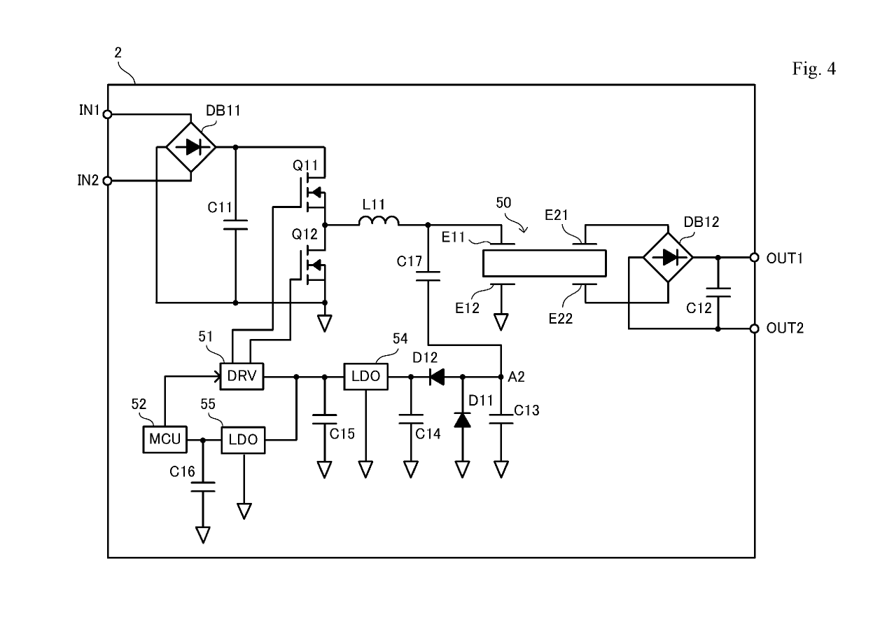

FIG. 4 is a circuit diagram of an AC adaptor 2 according to a second exemplary embodiment. In the first embodiment described above, the auxiliary power supply circuit is connected to the piezoelectric transformer 50. However, the second embodiment is different in that an auxiliary power supply circuit is connected between the piezoelectric transformer 50 and the inductor L11.

The capacitor C13 is connected between the inductor L11 and the input electrode E11 of the piezoelectric transformer 50 with a capacitor C17 interposed therebetween. A series circuit including the capacitors C17 and C13 is configured to be connected in parallel with the equivalent input capacitor 50A (see FIG. 2) of the piezoelectric transformer 50, and the composite capacitance of the parallel circuit and the inductor L11 form a resonance circuit. The capacitor C17 is an example of a “voltage dividing capacitor” according to the present disclosure.

The capacitance of the capacitor C17 is set less than or equal to the capacitance of the capacitor C13. In this case, regarding the impedance of the series circuit including the capacitors C17 and C13, the capacitor C17 is predominant. Therefore, a voltage to be applied to the series circuit including the capacitors C17 and C13 is determined mainly based on the capacitor C17. Furthermore, the potential of a connection point A2 of the capacitors C17 and C13 may be adjusted by the capacitor C13.

The other configurations are the same as those in the first embodiment. Therefore, explanation for the other configurations will be omitted.

As described above, the AC adaptor 2 according to this exemplary embodiment may achieve reduction in size by using the piezoelectric transformer 50, as in the first embodiment. In addition, an auxiliary power supply may be generated by connecting the capacitor C17 with the capacitor C13. Therefore, unlike conventional technologies, there is no need to configure a winding transformer, and, therefore, the size of the AC adaptor 2 can be reduced. Furthermore, the capacitors C17 and C13, together with the equivalent input capacitor 50A (see FIG. 2) of the piezoelectric transformer 50 and the inductor L11, form a resonance circuit. Therefore, a situation in which a plurality of resonance points appear may be prevented.

### Third Embodiment

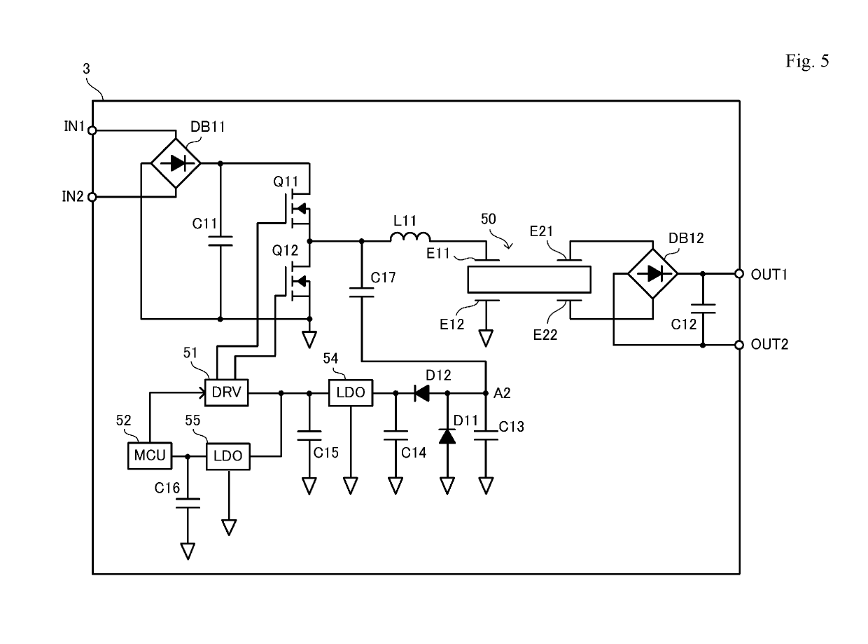

FIG. 5 is a circuit diagram of an AC adaptor 3 according to a third exemplary embodiment. In the second embodiment discussed above, the auxiliary power supply circuit is connected between the piezoelectric transformer 50 and the inductor L11. However, the third exemplary embodiment is different in that an auxiliary power supply circuit is connected between the inductor L11 and a connection point of the switching elements Q11 and Q12.

As shown, the capacitor C13 is connected between the inductor L11 and the connection point of the switching elements Q11 and Q12 with the capacitor C17 interposed therebetween. With this configuration, the equivalent input capacitor 50A (see FIG. 2) of the piezoelectric transformer 50 and the inductor L11 form a resonance circuit.

The capacitance of the capacitor C17 is set less than or equal to the capacitance of the capacitor C13. Furthermore, the capacitance of the equivalent input capacitor 50A of the piezoelectric transformer 50 is set less than or equal to the capacitance of the capacitor C13. A series circuit including the capacitors C17 and C13 is configured to be connected in parallel with the resonance circuit including the inductor L11 and the equivalent input capacitor 50A of the piezoelectric transformer 50. Therefore, due to setting of a constant mentioned above, the series circuit including the capacitors C17 and C13 has less effect on the resonance circuit.

Furthermore, regarding the impedance of the series circuit including the capacitors C17 and C13, the capacitor C17 is predominant. Therefore, a voltage to be applied to the series circuit including the capacitors C17 and C13 is determined by the capacitor C17. Furthermore, the potential of the connection point A2 of the capacitors C17 and C13 may be adjusted by the capacitor C13.

The other configurations are the same as those in the first exemplary embodiment. Therefore, explanation for the other configurations will be omitted.

As described above, the AC adaptor 3 according to this embodiment achieves reduction in size by using the piezoelectric transformer 50, as in the first and second exemplary embodiments. In addition, an auxiliary power supply may be generated by connecting the capacitor C17 with the capacitor C13. Therefore, there is no need to configure a winding transformer, unlike conventional designs, and reduction in size of the AC adaptor 3 is not hindered. Furthermore, the capacitors C17 and C13 have less effect on the resonance circuit formed by the equivalent input capacitor 50A of the piezoelectric transformer 50 and the inductor L11. Therefore, a situation in which a plurality of resonance points appear may be prevented.

It should be appreciated that an AC adaptor may be configured such that configurations of the auxiliary power supply circuits according to the first, second, and third embodiment are combined. The first and second embodiments may be combined, the first and third embodiments may be combined, or the first, second, and third embodiments may be combined. Furthermore, the second and third embodiments may be combined.

### Fourth Embodiment

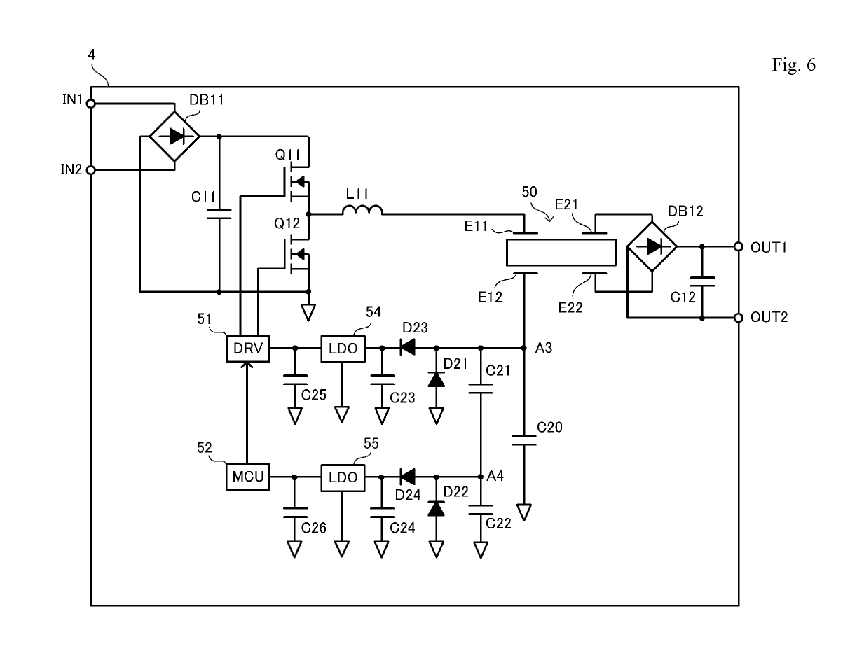

FIG. 6 is a circuit diagram of an AC adaptor 4 according to a fourth embodiment. This exemplary embodiment is different from the first embodiment in that an auxiliary power supply circuit is configured to generate voltages of different voltage values. The auxiliary power supply circuit according to this embodiment is connected to the input electrode E12 of the piezoelectric transformer 50.

A capacitor C20 is connected between the input electrode E12 of the piezoelectric transformer 50 and the ground. The equivalent input capacitor 50A (see FIG. 2) of the piezoelectric transformer 50, together with the capacitor C20 and the inductor L11, form a series resonance circuit. Two series circuits each including a rectifying and smoothing circuit and a voltage regulator are connected in parallel at a connection point A3 of the equivalent input capacitor 50A and the capacitor C20, and voltages to be applied to the driver 51 and the microcomputer 52 are output from the corresponding series circuits.

More particularly, a series circuit including capacitors C21 and C22 is connected in parallel with the capacitor C20. The capacitors C21 and C22 are examples of a “first reactance element” and an “auxiliary power supply capacitor” according to the present disclosure. A diode D21 is connected to the connection point A3. Furthermore, a rectifying and smoothing circuit including a diode D23 and a capacitor C23 is connected to the connection point A3. The diode D23 and the capacitor C23 rectify and smooth voltage at the connection point A3, and output the resultant voltage. The diode D23 and the capacitor C23 are an example of an “auxiliary-power-supply-side rectifying and smoothing circuit” according to the present disclosure.

The voltage regulator 54 is connected to an output side of the diode D23 and the capacitor C23. A bypass capacitor C25 and the driver 51 are connected to an output side of the voltage regulator 54. The voltage regulator 54 converts a voltage output from the diode D23 and the capacitor C23 into a voltage necessary for the driver 51 in the subsequent stage.

As further shown, a diode D22 is connected to a connection point A4 of the capacitors C21 and C22. Furthermore, a rectifying and smoothing circuit including a diode D24 and a capacitor C24 is connected to the connection point A4. The diode D24 and the capacitor C24 rectify and smooth the voltage at the connection point A4, and output the resultant voltage. The diode D24 and the capacitor C24 are an example of an “auxiliary-power-supply-side rectifying and smoothing circuit” according to the present disclosure.

The voltage regulator 55 is connected to an output side of the diode D24 and the capacitor C24. A bypass capacitor C26 and the microcomputer 52 are connected to an output side of the voltage regulator 55. The voltage regulator 55 converts a voltage output from the diode D24 and the capacitor C24 into a voltage necessary for the microcomputer 52 in the subsequent stage.

With this configuration, the equivalent input capacitor 50A of the piezoelectric transformer 50 is connected in series with a parallel circuit including the capacitor C20 and the series circuit including the capacitors C21 and C22. The capacitance of the capacitor C20 is set less than or equal to the composite capacitance of the series circuit including the capacitors C21 and C22. Therefore, regarding the impedance of the parallel circuit, the capacitor C20 is predominant. Furthermore, the capacitance of the equivalent input capacitor 50A of the piezoelectric transformer 50 is set less than or equal to the capacitance of the capacitor C20. Therefore, regarding the impedance of the series circuit including the equivalent input capacitor 50A and the parallel circuit, the equivalent input capacitor 50A is predominant.

Accordingly, the voltage to be applied to the series circuit including the equivalent input capacitor 50A of the piezoelectric transformer 50 and the parallel circuit is determined by the equivalent input capacitor 50A. Furthermore, the potential of the connection point A3 may be adjusted by the capacitor C20. Furthermore, the voltage at the connection point A4 may be adjusted by the capacitors C21 and C22.

According to this exemplary aspect, the potential of the connection point A3 is higher than the potential of the connection point A4. For example, let the potential of the connection point A3 be 18 V. In this case, the potential of the connection point A4 is equal to a voltage obtained by dividing the potential (18 V) at the connection point A3 by the capacitors C21 and C22. Let a voltage necessary for driving the driver 51 connected to the connection point A3 be 15 V, and let a voltage necessary for driving the microcomputer 52 connected to the connection point A4 be 3.3 V. In this case, the voltage regulator 54 steps down the voltage of 18 V to the voltage of 15 V. Furthermore, the voltage regulator 55 steps down the divided voltage of the voltage of 18 V to the voltage of 3.3 V.

In the auxiliary power supply circuit according to the first embodiment, the voltage regulator at the first stage (the voltage regulator 54 in FIG. 1) converts the voltage of 18 V into the voltage of 15 V, and the voltage regulator at the second stage (the voltage regulator 55 in FIG. 1) converts the voltage of 15 V into the voltage of 3.3 V, so that the driving voltage of the microcomputer 52 may be generated. In this case, there is a large difference in the voltage between before and after the conversion by the voltage regulator at the second stage, and the voltage difference thus causes a large loss.

In contrast, the voltage regulator 55 according to this embodiment converts the voltage at the connection point A4 into the voltage of 3.3 V for the microcomputer 52. In this case, the voltage difference between before and after the conversion by the voltage regulator 55 is smaller than the case where voltage regulators are configured as being two stages as in the first embodiment, and there is a smaller loss in the voltage regulator 55.

As described above, in this embodiment, loss at the time of stepping down the voltage at the voltage regulators 54 and 55 may be reduced, and driving voltages of the driver 51 and the microcomputer 52 may be generated.

In this example, the parallel circuit including the capacitor C20 and the series circuit including the capacitors C21 and C22 only needs to be capacitive, and the capacitor C20 may be replaced with a different element.

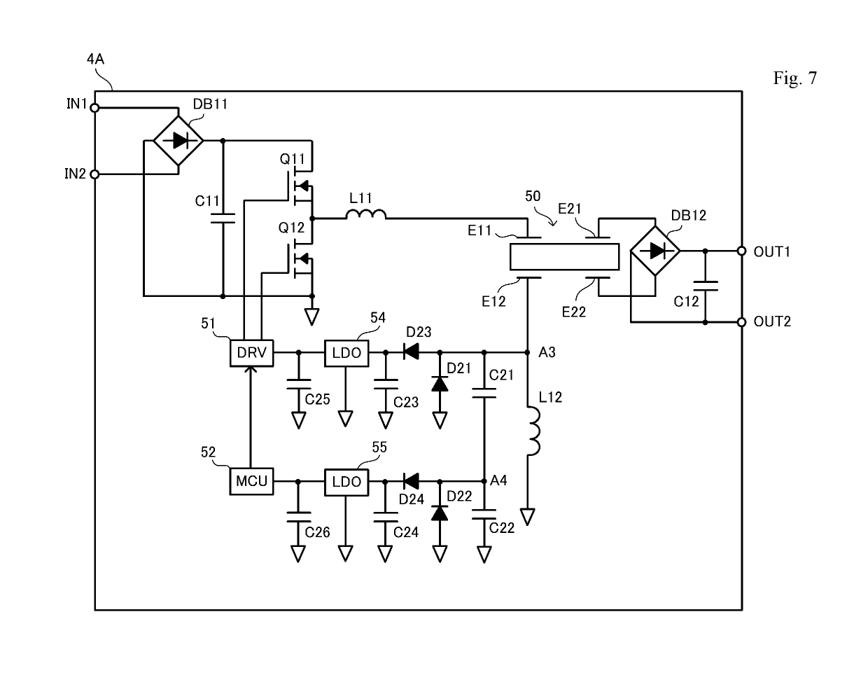

FIG. 7 is a circuit diagram of an AC adaptor 4A according to another example of the fourth embodiment. In this example, an inductor L12 is used in place of the capacitor C20 illustrated in FIG. 6. The inductor L12 corresponds to a “second reactance element” according to the present disclosure. In this case, a constant is set such that a parallel circuit including the inductor L12 and the series circuit including the capacitors C21 and C22 becomes capacitive at the switching frequencies of the switching elements Q11 and Q12. Even in this case, voltages of different voltage values may be output from the auxiliary power supply circuit, loss at the time of stepping down the voltage at the voltage regulators 54 and 55 may be reduced, and the driving voltages of the driver 51 and the microcomputer 52 may be generated.

Furthermore, the capacitor C20 illustrated in FIG. 6 may be omitted. In this case, only the capacitors C21 and C22 are configured to be connected between the input electrode E12 of the piezoelectric transformer 50 and the ground. Furthermore, although the diode D21 illustrated in FIGS. 6 and 7 is provided between the connection point A3 and the ground, the diode D21 may be configured to be connected in parallel with the capacitor C21.

### Fifth Embodiment

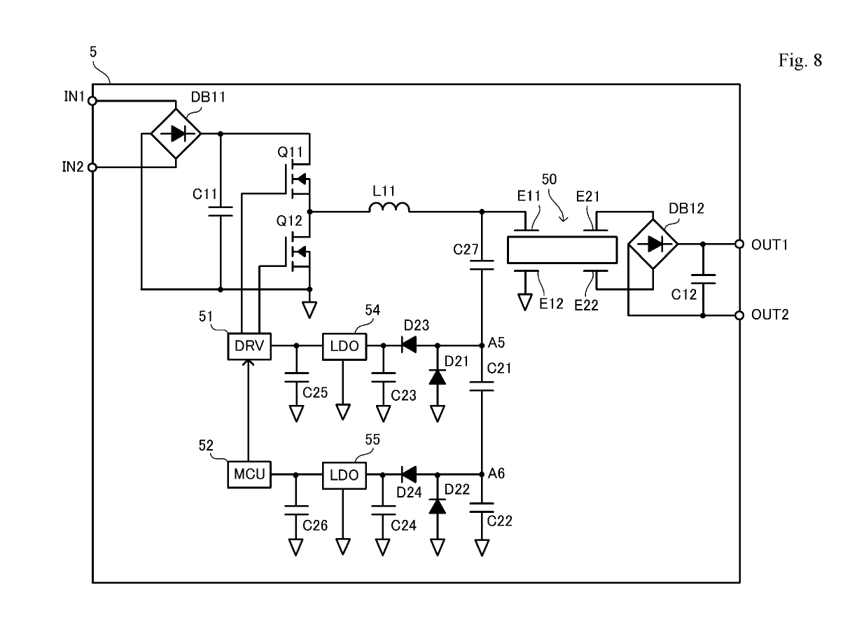

FIG. 8 is a circuit diagram of an AC adaptor 5 according to a fifth embodiment. In the fourth embodiment, the auxiliary power supply circuit is connected to the piezoelectric transformer 50. However, the fifth embodiment is different in that an auxiliary power supply circuit is connected between the piezoelectric transformer 50 and the inductor L11.

The capacitors C21 and C22 are connected between the inductor L11 and the input electrode E11 of the piezoelectric transformer 50. The series circuit including the capacitors C21 and C22 is configured to be connected in parallel with the equivalent input capacitor 50A (see FIG. 2) of the piezoelectric transformer 50, and the composite capacitance of the parallel circuit and the inductor L11 form a resonance circuit.

The capacitance of a capacitor C27 is set less than or equal to the capacitance of each of the capacitors C21 and C22. In this case, regarding the impedance of the series circuit including the capacitors C27, C21, and C22, the capacitor C27 is predominant. Therefore, the voltage to be applied to the series circuit is determined by the capacitor C27. Furthermore, the potential of a connection point A5 of the capacitors C27 and C21 and a connection point A6 of the capacitors C21 and C22 may be adjusted by the capacitors C21 and C22. The capacitor C27 is an example of a “voltage dividing capacitor” according to the present disclosure.

The other configurations are the same as those in the first exemplary embodiment. Therefore, explanation for the other configurations will be omitted.

Even with the above configuration, voltages of different voltage values may be output from the auxiliary power supply circuit, loss at the time of stepping down the voltage at the voltage regulators 54 and 55 may be reduced, and driving voltages of the driver 51 and the microcomputer 52 may be generated.

### Sixth Embodiment

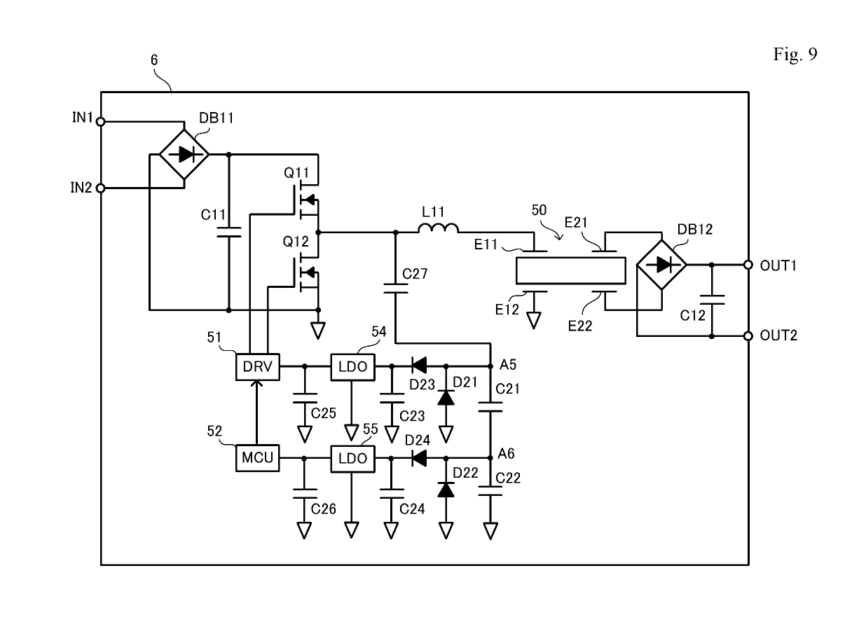

FIG. 9 is a circuit diagram of an AC adaptor 6 according to a sixth exemplary embodiment. In the fifth embodiment, the auxiliary power supply circuit is connected between the piezoelectric transformer 50 and the inductor L11. However, the sixth embodiment is different in that an auxiliary power supply circuit is connected between the inductor L11 and the connection point of the switching elements Q11 and Q12.

The capacitors C21 and C22 are connected between the inductor L11 and the connection point of the switching elements Q11 and Q12 with the capacitor C27 interposed therebetween. With this configuration, the equivalent input capacitor 50A (see FIG. 2) of the piezoelectric transformer 50 and the inductor L11 form a resonance circuit.

The capacitance of the capacitor C27 is set less than or equal to the capacitance of each of the capacitors C21 and C22. Furthermore, the capacitance of the equivalent input capacitor 50A of the piezoelectric transformer 50 is set less than or equal to the capacitance of the capacitor C27. The series circuit including the capacitors C27, C21, and C22 is configured to be connected in parallel with the resonance circuit including the inductor L11 and the equivalent input capacitor 50A of the piezoelectric transformer 50. Therefore, due to setting of a constant mentioned above, the series circuit including the capacitors C27, C21, and C22 have less effect on the resonance circuit.

Furthermore, regarding the impedance of the series circuit including the capacitors C27, C21, and C22, the capacitor C27 is predominant. Therefore, the voltage to be applied to the series circuit including the capacitors C27, C21, and C22 is determined by the capacitor C27. Furthermore, the potential of the connection point A5 of the capacitors C27 and C21 and the connection point A6 of the capacitors C21 and C22 may be adjusted by the capacitors C21 and C22.

The other configurations are the same as those in the first exemplary embodiment. Therefore, explanation for the other configurations will be omitted.

Even with this configuration, voltages of different voltage values may be output from the auxiliary power supply circuit, loss at the time of stepping down the voltage at the voltage regulators 54 and 55 may be reduced, and driving voltages of the driver 51 and the microcomputer 52 may be generated.

The AC adaptor may be configured such that configurations of the auxiliary power supply circuits according to the first to sixth embodiments are combined.

In the first to sixth embodiments, a capacitive circuit including a capacitor is connected to a piezoelectric transformer, so that reduction in size of an AC adaptor may be achieved. In contrast, in seventh to tenth embodiments described below, an inductive circuit is connected to a piezoelectric transformer, so that reduction in size of an AC adaptor may be achieved.

### Seventh Embodiment

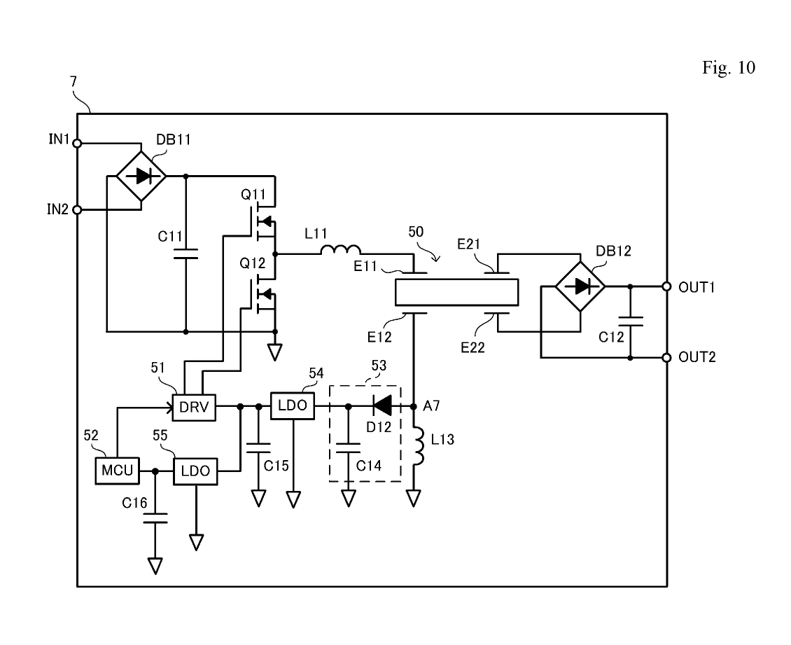

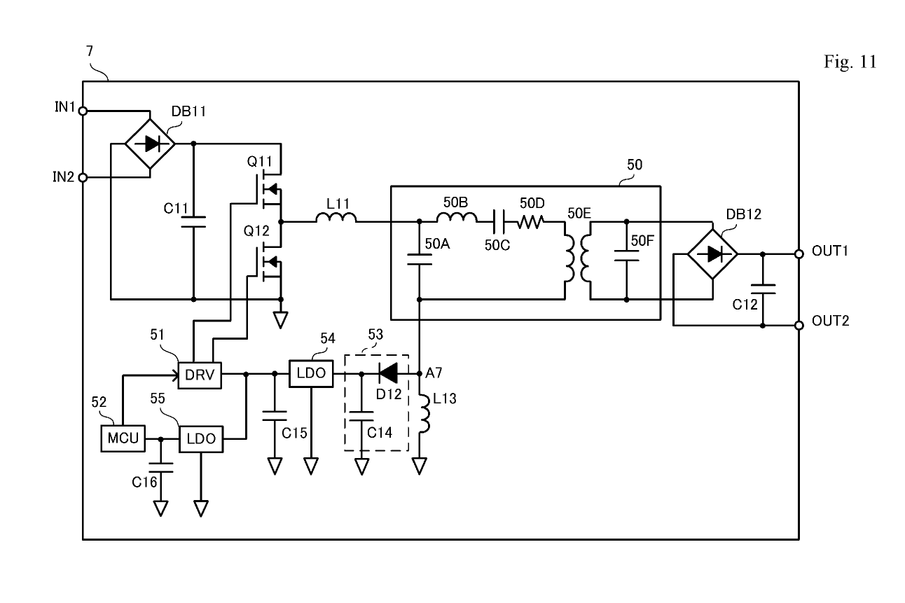

FIG. 10 is a circuit diagram of an AC adaptor 7 according to a seventh embodiment. FIG. 11 is a circuit diagram of the AC adaptor 7 in which the piezoelectric transformer 50 illustrated in FIG. 10 is represented by an equivalent circuit.

The AC adaptor 7 includes the input units IN1 and IN2 that are connected to a commercial power supply and input an AC voltage from the commercial power supply and the output units OUT1 and OUT2 that are connected to loads and output a DC voltage to the loads. The AC adaptor 7 is an example of a “power supply circuit” according to the present disclosure.

The diode bridge DB11 is connected to the input units IN1 and IN2. The smoothing capacitor C11 is also connected to the diode bridge DB11. AC voltages input from the input units IN1 and IN2 are rectified and smoothed by the diode bridge DB11 and the smoothing capacitor C11. The diode bridge DB11 and the smoothing capacitor C11 are an example of an “input-side rectifying and smoothing circuit” according to the present disclosure.

The switching elements Q11 and Q12 that are connected in series are connected to the diode bridge DB11 and the smoothing capacitor C11. In FIGS. 10 and 11, the switching elements Q11 and Q12 are n-type MOS-FETs. However, the switching elements Q11 and Q12 may be IGBTs, bipolar transistors, or the like. The voltage that has been rectified and smoothed by the diode bridge DB11 and the like is converted into a voltage of a rectangular wave by switching of the switching elements Q11 and Q12. The switching elements Q11 and Q12 that are connected in series are an example of a “switching circuit” according to the present disclosure. The driver (DRV) 51 is connected to the gates of the switching elements Q11 and Q12. Furthermore, the microcomputer (MCU) 52 is connected to the driver 51. Under feedback control, the microcomputer 52 considers the weight of the loads connected to the output units OUT1 and OUT2, and sets the switching frequencies of the switching elements Q11 and Q12 in accordance with the weight of the loads. The driver 51 generates gate voltages in accordance with a control signal from the microcomputer 52, applies the gate voltages to the switching elements Q11 and Q12, and turns on and off the switching elements Q11 and Q12 at cycles set by the microcomputer 52. The driver 51 is an example of a “driver circuit” according to the present disclosure. The microcomputer 52 is an example of a “controller circuit” or “controller” according to the present disclosure.

The piezoelectric transformer 50 is connected to the switching elements Q11 and Q12. The piezoelectric transformer 50 is of an insulation type, and includes the input electrodes E11 and E12 and the output electrodes E21 and E22. The input electrodes E11 and E12 are an example of a “pair of voltage input electrodes” according to the present disclosure. The output electrodes E21 and E22 are an example of a “pair of voltage output electrodes” according to the present disclosure.

The input electrode E11 of the piezoelectric transformer 50 is connected to the connection point of the switching elements Q11 and Q12 with the inductor L11 interposed therebetween. The input electrode E12 of the piezoelectric transformer 50 is connected to the source of the switching element Q12 via the ground. The input electrode E12 and the switching element Q12 are connected via the ground, thereby the circuit being simplified.

The output electrodes E21 and E22 of the piezoelectric transformer 50 are connected to the diode bridge DB12. The smoothing capacitor C12 is connected to the diode bridge DB12, and is also connected to the output units OUT1 and OUT2. The diode bridge DB12 and the smoothing capacitor C12 correspond to an “output-side rectifying and smoothing circuit”.

The piezoelectric transformer 50 is equivalently represented by the capacitors 50A, 50C, and 50F, the inductor 50B, the resistor 50D, the ideal transformer 50E, and the like, as illustrated in FIG. 11. The capacitor 50A represents an equivalent input capacitance of the piezoelectric transformer 50, and the capacitor 5OF represents an equivalent output capacitance of the piezoelectric transformer 50. Furthermore, the inductor 50B, the capacitor 50C, and the like are parameters representing electromechanical coupling.

The capacitor 50A, which represents an equivalent input capacitance of the piezoelectric transformer 50, and the inductor L11, which is connected to the input electrode E11, form a series resonance circuit. The voltage waveform is converted into a rectangular wave by the switching elements Q11 and Q12. However, with the series resonance circuit, a sine wave is always input to the piezoelectric transformer 50. The piezoelectric transformer 50 steps down the voltage input from the input electrodes E11 and E12 and causes the resultant voltage to be output from the output electrodes E21 and E22. The voltage obtained by stepping down a voltage by the piezoelectric transformer 50 is rectified and smoothed by the diode bridge DB12 and the smoothing capacitor C12, and output from the output units OUT1 and OUT2.

An auxiliary power supply circuit is connected to the input electrode E12 of the piezoelectric transformer 50. The driving voltages of the driver 51 and the microcomputer 52 are much lower than the voltage of the commercial power supply input to the AC adaptor 7. Therefore, the voltage of the commercial power supply cannot be used directly as the driving voltage of the driver 51 or the like. Thus, an auxiliary power supply circuit is provided separately, and a predetermined voltage is obtained based on the voltage applied to the piezoelectric transformer 50, so that the driving voltages of the driver 51 and the microcomputer 52 can be generated. The auxiliary power supply circuit includes an inductor L13, a rectifying and smoothing circuit 53, the voltage regulators (LDOs) 54 and 55, the bypass capacitors C15 and C16, and the like.

One end of the inductor L13 is connected to the input electrode E12 of the piezoelectric transformer 50, and the other end of the inductor L13 is connected to the ground. A constant is set for the inductor L13 to be sufficiently small (for example, 1/10) with respect to the impedance of the capacitor 50A, which represents the equivalent input capacitance of the piezoelectric transformer 50. The inductor L13 is an example of a “first reactance element” and an “inductive circuit” according to the present disclosure.

The inductor L13 is an inductive element. Furthermore, the piezoelectric transformer 50 is a capacitive device. That is, it may be considered that a configuration in which a capacitive element and an inductive element are connected in series is provided. In the case where a voltage is applied to the piezoelectric transformer 50 from the switching elements Q11 and Q12, a voltage to be applied to the inductor L13 may be obtained from a connection point A7 of the piezoelectric transformer 50 and the inductor L13. In the series circuit including the capacitive element and the inductive element, the bigger the inductance of the inductive element, the higher the voltage applied to the inductive element. Therefore, with the use of the inductor L13, which is an inductive element, a larger voltage may be obtained.

The rectifying and smoothing circuit 53 is connected to the connection point A7. The rectifying and smoothing circuit 53 includes the diode D12 and the capacitor C14. The rectifying and smoothing circuit 53 extracts a voltage applied to the inductor L13, and performs rectification and smoothing of the voltage. The rectifying and smoothing circuit 53 is an example of an “auxiliary-power-supply-side rectifying and smoothing circuit” according to the present disclosure.

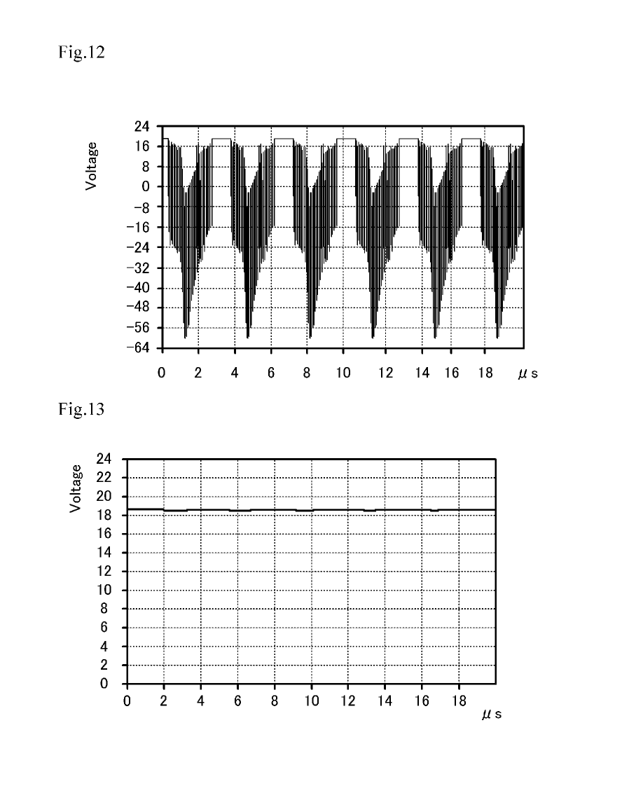

FIG. 12 is a diagram illustrating a voltage waveform at the connection point A7 of the piezoelectric transformer 50 and the inductor L13. The voltage at the connection point A7 is also defined as an input voltage of the rectifying and smoothing circuit 53. FIG. 13 is a diagram illustrating an output voltage waveform of the rectifying and smoothing circuit 53. In FIGS. 12 and 13, the horizontal axis represents time [μs] and the vertical axis represents voltage [V]. As illustrated in FIGS. 12 and 13, in this embodiment, the inductor L13 having an inductance of 30 μH is provided, and a voltage of about 18 V is obtained from the voltage applied to the piezoelectric transformer 50.

The voltage regulator 54 is connected to an output side of the rectifying and smoothing circuit 53. The bypass capacitor C15 for smoothing and the driver 51 are connected to an output side of the voltage regulator 54. The voltage regulator 54 converts the voltage output from the rectifying and smoothing circuit 53 into a voltage necessary for the driver 51 in the subsequent stage. For example, as illustrated in FIG. 13, in a case where a voltage of 18 V is output from the rectifying and smoothing circuit 53 and a voltage necessary for driving the driver 51 is 12 V, the voltage regulator 54 converts the input voltage of 18 V into a voltage of 12 V and outputs the resultant voltage. Accordingly, the driver 51 drives the gates of the switching elements Q11 and Q12.

Furthermore, the voltage regulator 55 is also connected to the output side of the voltage regulator 54. The bypass capacitor C16 for smoothing and the microcomputer 52 are connected to an output side of the voltage regulator 55. The voltage regulator 55 converts the voltage output from the voltage regulator 54 into a voltage necessary for driving the microcomputer 52 in the subsequent stage. For example, in the case where the voltage necessary for operation of the microcomputer 52 is 3.3 V, the voltage regulator 55 converts the voltage of 12 V converted by and output from the voltage regulator 54 into a voltage of 3.3 V and outputs the resultant voltage, as described above. Accordingly, the microcomputer 52 operates.

As described above, with the provision of the voltage regulators 54 and 55, a constant voltage of a desired value may be output based on an extracted voltage.

The voltage regulators 54 and 55 are connected in cascade to the rectifying and smoothing circuit 53 to generate the operating voltage of the microcomputer 52. With this configuration, a decrease in the efficiency of the auxiliary power supply circuit may be prevented. More particularly, in the above example, the voltage obtained from the connection point A7 is about 18 V, the driving voltage of the microcomputer 52 is 3.3 V, and there is a large difference between these voltages. Therefore, in the case where one voltage regulator converts the voltage of 18 V into the voltage of 3.3 V, there is a large loss in the auxiliary power supply circuit. Thus, by causing the voltage regulator 54 to convert the voltage of 18 V into the voltage of 12 V and then causing the voltage regulator 55 to convert the voltage of 12 V into the voltage of 3.3 V, loss in the auxiliary power supply circuit may be reduced, and efficiency may be increased.

As described above, the AC adaptor 7 according to this embodiment achieves reduction in size by using the piezoelectric transformer 50. An auxiliary power supply may be generated by connecting the inductor L13 to the piezoelectric transformer 50. As a result, there is no need to configure a winding transformer, and a reduction in size of the AC adaptor 7 can be achieved. Furthermore, the inductance of the inductor L13 is sufficiently smaller than the inductance of the inductor L11, and providing the inductor L13 does not affect the resonance characteristics of the resonance circuit including the inductor L11 and the capacitor 50A. Therefore, a constant may be set for the inductor L13 alone without being restricted by the resonance characteristics of the resonant circuit. Thus, the auxiliary power supply circuit may be designed easily, and versatility of the auxiliary power supply circuit may be increased.

Although not illustrated in figures, the AC adaptor 7 may include a starting circuit. The starting circuit generates the driving voltages of the driver 51 and the microcomputer 52 based on the commercial power supply voltage during a period from activation of the AC adaptor 7 until starting of switching of the switching elements Q11 and Q12. Then, after the microcomputer 52 and the like start and switching of the switching elements Q11 and Q12 starts, the starting circuit stops. The auxiliary power supply circuit extracts a voltage from the commercial power supply voltage applied to the piezoelectric transformer 50, and thus generates the driving voltages of the driver 51 and the like. Accordingly, during a period from activation of the AC adaptor 7 until driving of the auxiliary power supply circuit, the driver 51 and the like may be driven appropriately.

### Eighth Embodiment

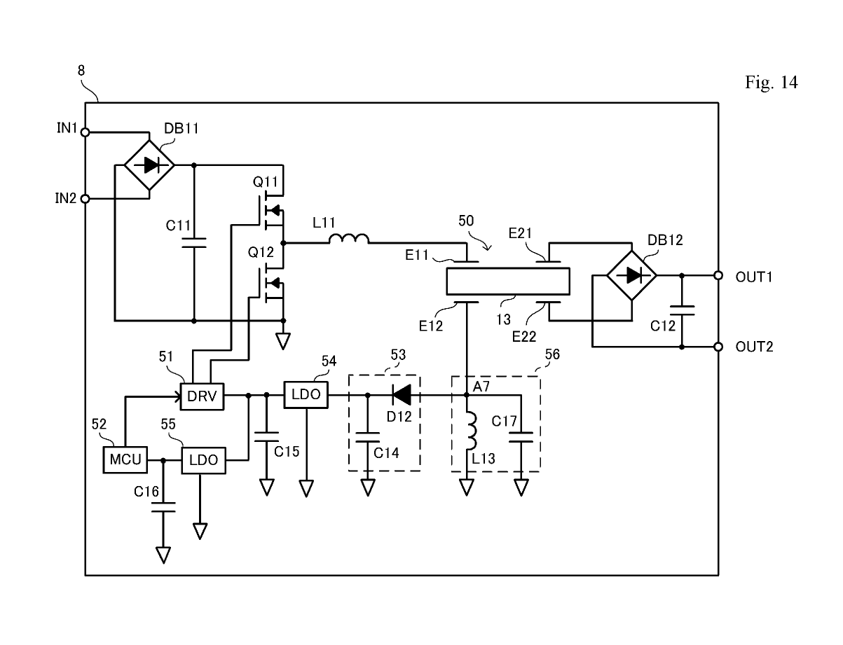

FIG. 14 is a circuit diagram of an AC adaptor 8 according to an eighth embodiment. This embodiment is different from the seventh embodiment in the configuration of an auxiliary power supply circuit included in the AC adaptor 8. The difference will be described below.

In the auxiliary power supply circuit of the AC adaptor 8, the capacitor C17 is connected in parallel with the inductor L13, so that a parallel circuit 56 is formed. Constants are set for the inductor L13 and the capacitor C17 such that the parallel circuit 56 becomes inductive at the switching frequencies of the switching elements Q11 and Q12. The parallel circuit 56 is an example of an “inductive circuit” according to the present disclosure.

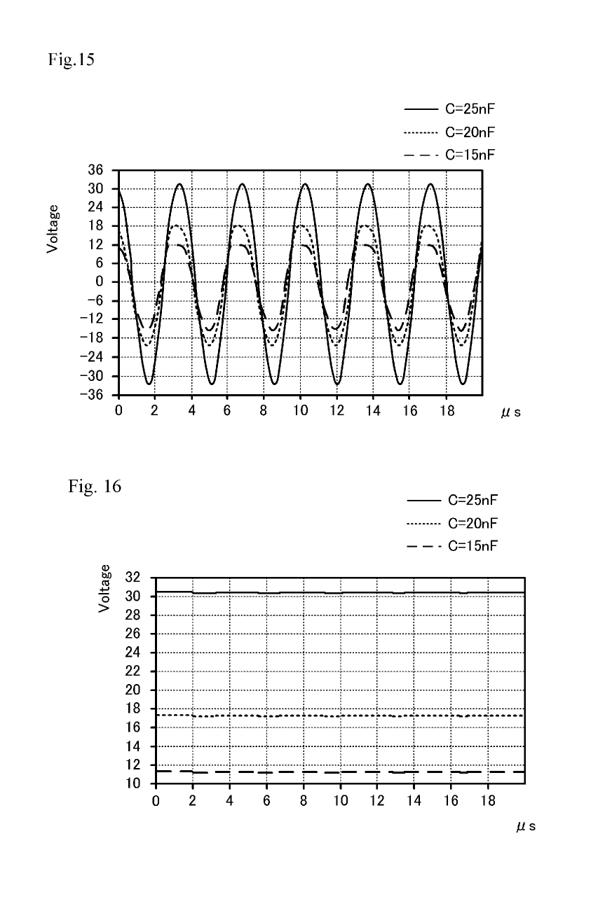

FIG. 15 is a diagram illustrating a voltage waveform at the connection point A7 of the piezoelectric transformer 50 and the inductor L13. FIG. 16 is a diagram illustrating an output voltage waveform of the rectifying and smoothing circuit 53. In FIGS. 15 and 16, the horizontal axis represents time [μs] and the vertical axis represents voltage [V]. Furthermore, in FIGS. 15 and 16, voltage waveforms for the case where the inductance of the inductor L13 is set to 10 μH and the capacitance of the capacitor C17 is set to 15 nF, 20 nF, and 25 nF.

As illustrated in FIGS. 15 and 16, different voltages may be obtained by varying the capacitance of the capacitor C17. For example, in the case where the capacitance of the capacitor C17 is 25 nF, a voltage of about 30 V may be obtained. In the case where the capacitance of the capacitor C17 is 20 nF, a voltage of about 18 V may be obtained. In the case where the capacitance of the capacitor C17 is 15 nF, a voltage of about 12 V may be obtained.

As described above, by appropriately varying the capacitance of the capacitor C17 that is connected in parallel with the inductor L13, a voltage to be extracted may be adjusted. A constant may be set for the capacitor C17 in accordance with the voltage necessary for driving a subsequent element connected to the rectifying and smoothing circuit 53, for example, the driver 51 or the microcomputer 52.

Furthermore, in the case where the capacitor C17 is connected in parallel, noise appearing in the voltage waveform may be reduced compared to the seventh embodiment (see FIG. 12) in which the capacitor C17 is not provided. In the seventh embodiment in which the capacitor C17 is not provided, the inductor L13 resonates with the parasitic capacitance (junction capacitance) of the diode D12, and the resonance causes noise (spikes) in the voltage waveform in FIG. 12 to appear. In contrast, in this embodiment in which the capacitor C17 is provided, the capacitance of the capacitor C17 is sufficiently larger than the parasitic capacitance of the diode D12, and the parasitic capacitance of the diode D12 may be negligible (invisible). Then, the inductor L13 resonates with the capacitor C17. The resonant frequency is low enough to approximate the switching frequencies of the switching elements Q11 and Q12. Accordingly, noise (spikes) in the voltage waveform in FIG. 12 does not appear.

Furthermore, in the case where noise appears in the voltage waveform at the connection point A7, the diode D12 of the rectifying and smoothing circuit 53 needs to be a high-resistance element for consideration of noise. In this embodiment, however, there is no need to use a high-resistance element for the diode D12 because noise does not appear.

### Ninth Embodiment

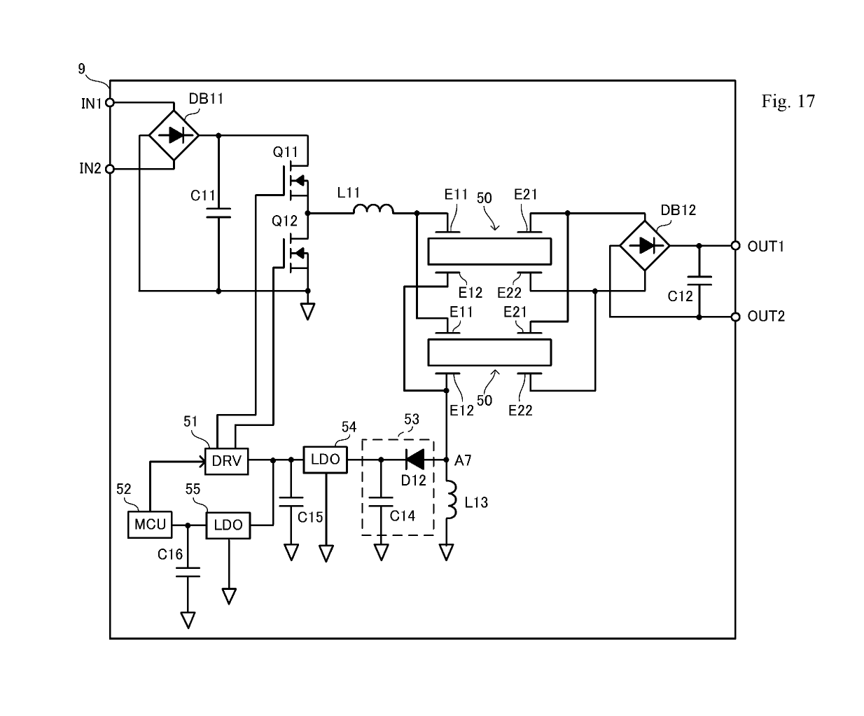

FIG. 17 is a circuit diagram of an AC adaptor 9 according to a ninth embodiment. This embodiment is different from the seventh embodiment in that the AC adaptor 9 includes two piezoelectric transformers 50 that are connected in parallel. The difference will be described below.

The two piezoelectric transformers 50 are connected in parallel. The input electrodes E11 of the two piezoelectric transformers 50 are connected to the connection point of the switching elements Q11 and Q12 with the inductor L11 interposed therebetween. An auxiliary power supply circuit is connected to the input electrodes E12 of the two piezoelectric transformers 50. The auxiliary power supply circuit has the same configuration as that in the seventh embodiment. The output electrodes E21 and E22 of the two piezoelectric transformers 50 are connected to the diode bridge DB12.

As described above, the AC adaptor 9 according to this embodiment has a configuration in which two piezoelectric transformers are connected in parallel. From the point of view of resonance characteristics and mechanical strength, the size of a piezoelectric transformer is restricted, and the amount of power that can be handled is restricted by the size restriction. Thus, by connecting two piezoelectric transformers in parallel as in this exemplary embodiment, the AC adaptor 9 is configured to handle a large amount of power, and there is no need to configure a winding transformer as compared with known technologies.

Furthermore, as in the seventh embodiment, by connecting the inductor L13 to the piezoelectric transformers 50, an auxiliary power supply may be generated for each of the driver 51 and the microcomputer 52. Therefore, there is no need to provide a winding transformer, and reduction in size of the AC adaptor 9 is not hindered.

The auxiliary power supply circuit according to this embodiment may have a configuration in which a capacitor is connected in parallel with the inductor L13 of the auxiliary power supply circuit, as explained in the eighth embodiment.

### Tenth Embodiment

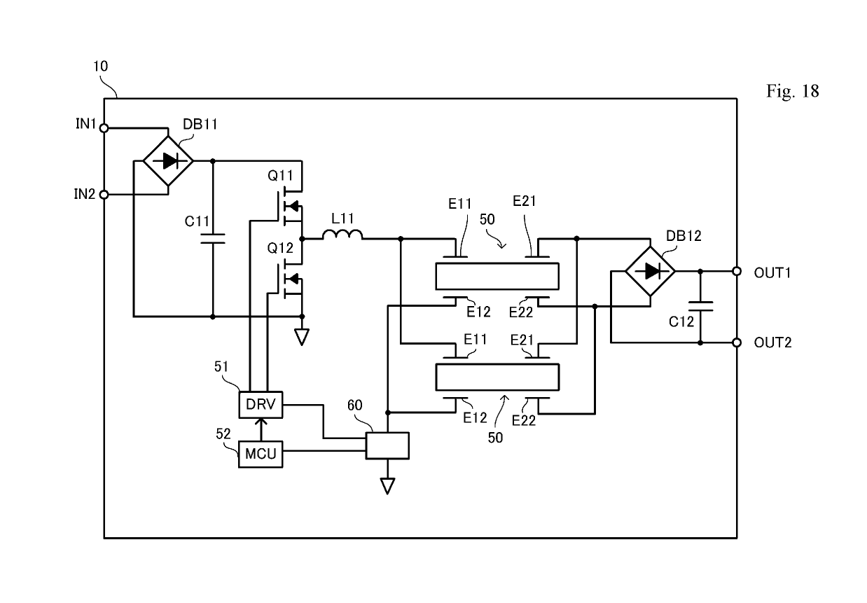

FIG. 18 is a circuit diagram of an AC adaptor 10 according to a tenth exemplary embodiment. The tenth embodiment is different from the ninth embodiment in the configuration of an auxiliary power supply circuit included in the AC adaptor 10. The difference will be described below. In this embodiment, the AC adaptor 10 has a configuration in which two piezoelectric transformers 50 are connected in parallel. However, the AC adaptor 10 may be configured to include only one piezoelectric transformer, as in the seventh embodiment.

The input electrodes E11 of the two piezoelectric transformers 50 that are connected in parallel are connected to the connection point of the switching elements Q11 and Q12 with the inductor L11 interposed therebetween. An auxiliary power supply circuit 60 is connected to the input electrodes E12 of the two piezoelectric transformers 50. The output electrodes E21 and E22 of the two piezoelectric transformers 50 are connected to the diode bridge DB12.

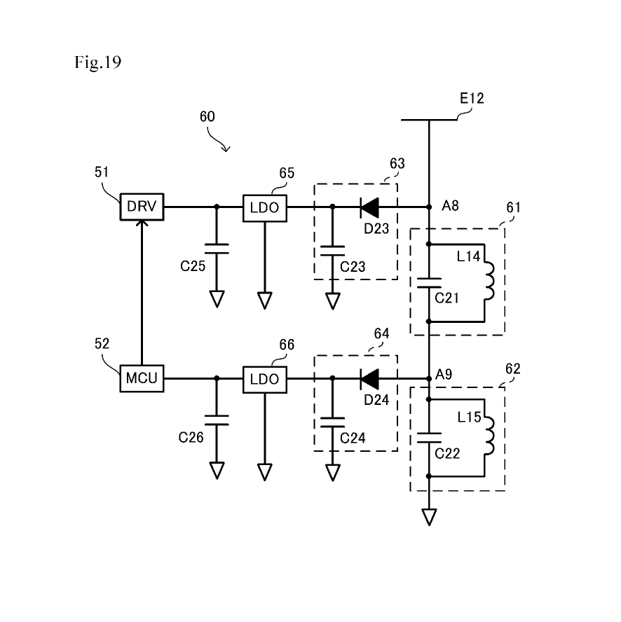

FIG. 19 is a circuit diagram of the auxiliary power supply circuit 60 according to this embodiment.

The auxiliary power supply circuit 60 generates voltages of different voltage values based on voltages applied to the two piezoelectric transformers 50, and applies the generated voltages to the driver 51 and the microcomputer 52. The auxiliary power supply circuit 60 includes parallel circuits 61 and 62. The parallel circuit 61 is formed by the capacitor C21 and an inductor L14 that are connected in parallel. The parallel circuit 62 is formed by the capacitor C22 and an inductor L15 that are connected in parallel. The inductors L14 and L15 are examples of a “first reactance element” according to the present disclosure.

The parallel circuits 61 and 62 are connected in series between the input electrode E12 of the piezoelectric transformer 50 and the ground. Constants are set such that the parallel circuits 61 and 62 become inductive at the switching frequencies of the switching elements Q11 and Q12. The parallel circuits 61 and 62 are examples of an “inductive circuit” according to the present disclosure. The inductors L14 and L15 are examples of a “series connection unit” according to the present disclosure.

In the explanation provided below, a connection point of the input electrode E12 of the piezoelectric transformer 50 and the parallel circuit 61 will be referred to as a connection point A8. A connection point of the parallel circuits 61 and 62 will be referred to as a connection point A9.

The auxiliary power supply circuit 60 includes rectifying and smoothing circuits 63 and 64, voltage regulators (LDOs) 65 and 66, and bypass capacitors C25 and C26.

The rectifying and smoothing circuit 63 includes the diode D23 and the capacitor C23. The rectifying and smoothing circuit 63 is connected to the connection point A8. The rectifying and smoothing circuit 64 includes the diode D24 and the capacitor C24. The rectifying and smoothing circuit 64 is connected to the connection point A9. The rectifying and smoothing circuits 63 and 64 extract voltages at the connection points A8 and A9, and rectifies and smooths the extracted voltages. The rectifying and smoothing circuits 63 and 64 are examples of an “auxiliary-power-supply-side rectifying and smoothing circuit” according to the present disclosure.

The potential of the connection point A8 is determined by the composite impedance of the parallel circuits 61 and 62. Furthermore, the potential of the connection point A9 is determined by the ratio of impedances of the parallel circuits 61 and 62. Therefore, the potentials of the connection points A8 and A9 may be adjusted by adjusting the impedances of the parallel circuits 61 and 62.

The voltage regulators 65 and 66 are connected to output sides of the rectifying and smoothing circuits 63 and 64. The bypass capacitor C25 for smoothing and the driver 51 are connected to an output side of the voltage regulator 65. The voltage regulator 65 converts the voltage output from the rectifying and smoothing circuit 63 into a voltage necessary for the driver 51 in the subsequent stage. The bypass capacitor C26 for smoothing and the microcomputer 52 are connected to an output side of the voltage regulator 66. The voltage regulator 66 converts the voltage output from the rectifying and smoothing circuit 64 into a voltage necessary for the microcomputer 52 in the subsequent stage.

In this aspect, the potential of the connection point A8 is higher than the potential of the connection point A9. For example, let the potential of the connection point A8 be 18 V. In this case, the potential of the connection point A9 is equal to a voltage obtained by dividing the potential (18 V) of the connection point A8 by the parallel circuits 61 and 62. Moreover, let a voltage necessary for driving the driver 51 that is connected to the connection point A8 with the rectifying and smoothing circuit 63 and the like interposed therebetween be 15 V, and let a voltage necessary for driving the microcomputer 52 that is connected to the connection point A9 with the rectifying and smoothing circuit 64 and the like interposed therebetween be 3.3 V. In this case, the voltage regulator 65 converts the voltage of 18 V into the voltage of 15 V. Furthermore, the voltage regulator 66 converts the voltage of 18 V into the voltage of 3.3 V.

In the auxiliary power supply circuit according to the seventh embodiment, the voltage regulator at the first stage (the voltage regulator 54 in FIG. 10) converts a voltage of 18 V into a voltage of 15 V, the voltage regulator at the second stage (the voltage regulator 55 in FIG. 10) converts a voltage of 15 V into a voltage of 3.3 V, and the driving voltage of the microcomputer 52 is thus generated. In this case, there is a large voltage difference between before and after the conversion at the voltage regulator at the second stage, and the voltage difference causes a large loss.

In contrast, in this embodiment, the voltage regulator 66 converts the division voltage of the voltage at the connection point A8 into a voltage of 3.3 V for the microcomputer 52. In this case, the voltage difference between before and after the voltage conversion by the voltage regulator 66 is smaller than the case where voltage regulators at two stages are configured as in the seventh embodiment, and loss caused by the voltage difference at the voltage regulator 66 is small.

As described above, with the configuration in which the parallel circuits 61 and 62 are connected in series and the rectifying and smoothing circuits 63 and 64 are connected to the connection points A8 and A9, loss at the time of stepping down the voltage at the voltage regulators 65 and 66 may be reduced, and driving voltages of the driver 51 and the microcomputer 52 may be generated.

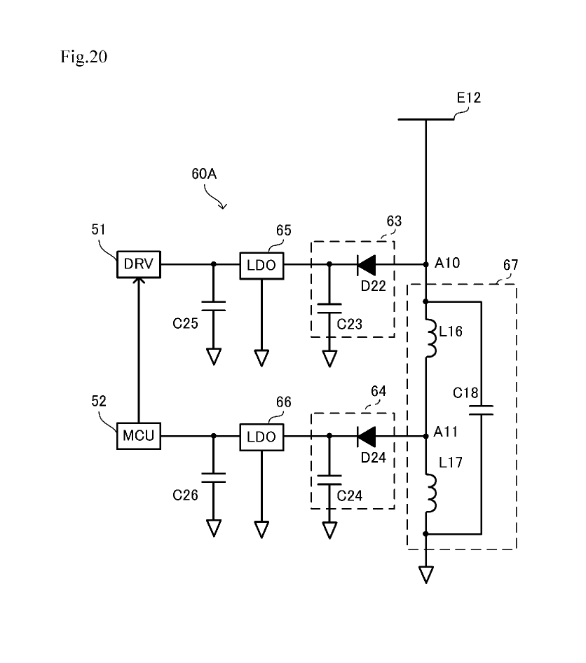

FIGS. 20, 21, and 22 are circuit diagrams of other examples of an auxiliary power supply circuit according to various exemplary embodiments.

As shown, an auxiliary power supply circuit 60A illustrated in FIG. 20 includes a parallel circuit 67 between the input electrode E12 of the piezoelectric transformer 50 and the ground. The parallel circuit 67 is configured such that a series circuit including inductors L16 and L17 and a capacitor C18 are connected in parallel. Constants are set for the inductors L16 and L17 and the capacitor C18 such that the parallel circuit 67 becomes inductive at the switching frequencies of the switching elements Q11 and Q12. The parallel circuit 67 is an example of an “inductive circuit” according to the present disclosure. The inductors L16 and L17 are examples of a “first reactance element” and a “series connection unit” according to the present disclosure.

The rectifying and smoothing circuit 63 is connected to a connection point A10 of the input electrode E12 of the piezoelectric transformer 50 and the inductor L16. The rectifying and smoothing circuit 64 is connected to a connection point A11 of the inductors L16 and L17. The potential of the connection point A11 may be adjusted by adjusting the impedance of the parallel circuit 67 and the ratio of impedances of the inductors L16 and L17.

Even with this configuration, loss at the time of stepping down the voltage at the voltage regulators 65 and 66 may be reduced, and driving voltages of the driver 51 and the microcomputer 52 may be generated according to the exemplary aspect.

An auxiliary power supply circuit 60B illustrated in FIG. 21 further includes an inductor L18 that is connected in parallel with the parallel circuit 67. By further providing the inductor L18, the potential of the connection point A11 may be adjusted.

Even with this configuration, loss at the time of stepping down the voltage at the voltage regulators 65 and 66 may be reduced, and driving voltages of the driver 51 and the microcomputer 52 may be generated according to the exemplary aspect.

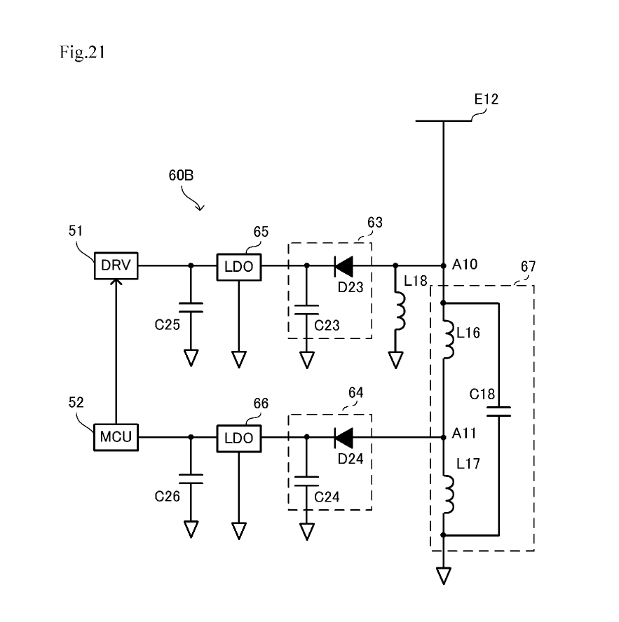

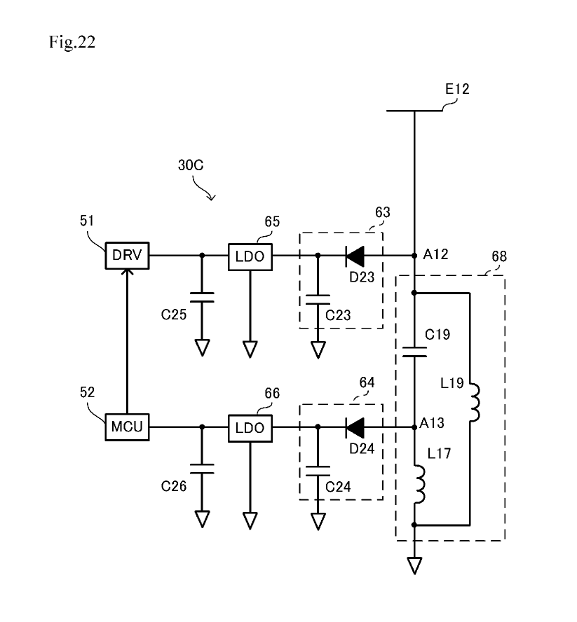

An auxiliary power supply circuit 60C illustrated in FIG. 22 includes a parallel circuit 68 between the input electrode E12 of the piezoelectric transformer 50 and the ground. The parallel circuit 68 is configured such that a series circuit including a capacitor C19 and the inductor L17 and an inductor L19 are connected in parallel. A constant is set such that the parallel circuit 68 becomes inductive at the switching frequencies of the switching elements Q11 and Q12. The parallel circuit 68 is an example of an “inductive circuit” according to the present disclosure.

The rectifying and smoothing circuit 63 is connected to a connection point A12 of the input electrode E12 of the piezoelectric transformer 50 and the inductor L19. The rectifying and smoothing circuit 64 is connected to a connection point A13 of the capacitor C19 and the inductor L17. The potentials of the connection points A12 and A13 may be adjusted by adjusting the impedance of the parallel circuit 68 and the ratio of impedances of the capacitor C19 and the inductor L17.

Even with this configuration, loss at the time of stepping down the voltage at the voltage regulators 65 and 66 may be reduced, and driving voltages of the driver 51 and the microcomputer 52 may be generated according to the exemplary aspect.

According to the first to tenth exemplary embodiments, reduction in size of an AC adaptor may be achieved as described above. In eleventh to fifteenth embodiments described below, configurations of AC adaptors that are capable of stably outputting an auxiliary power supply voltage from an auxiliary power supply circuit will be described.

In the case where an auxiliary power supply voltage is generated based on an input voltage or an input current, ripples appear in input voltage due to variations in the weight of a load. The ripples may affect the auxiliary power supply voltage (voltage for an IC) to be generated. For example, in the case where influence of the ripples causes a voltage input to an IC from an auxiliary power supply to be lower than the driving voltage of the IC, there is a possibility that the IC may not be driven normally. Furthermore, in the case where the ripples cause a voltage that exceeds the driving voltage of the IC to be output from the auxiliary power supply, the voltage needs to be stepped down by a constant voltage circuit in accordance with the driving voltage of the IC, and a large loss occurs in the constant voltage circuit. The auxiliary power supply circuits described below in the eleventh to fifteenth embodiments may output a stable auxiliary power supply voltage.

### Eleventh Embodiment

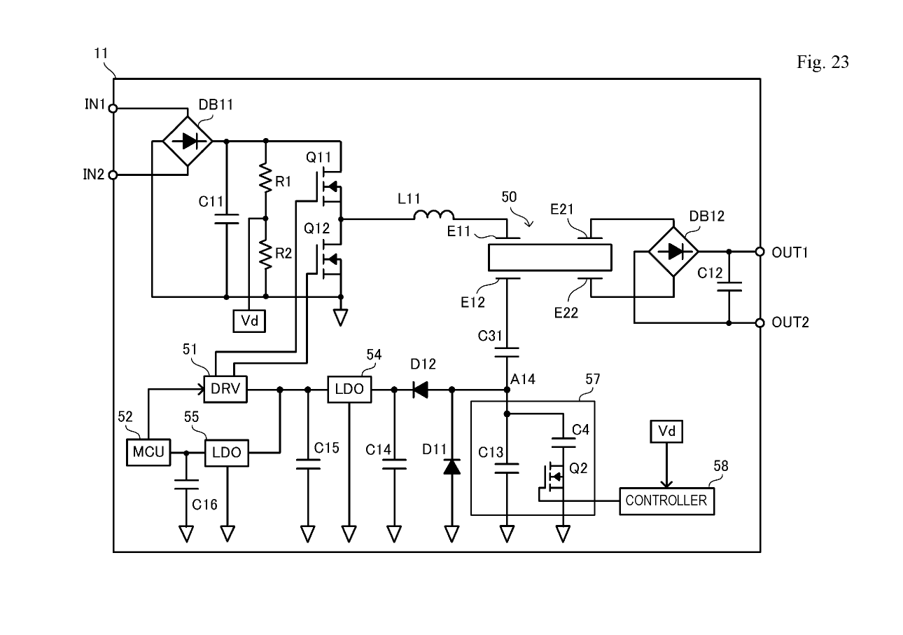

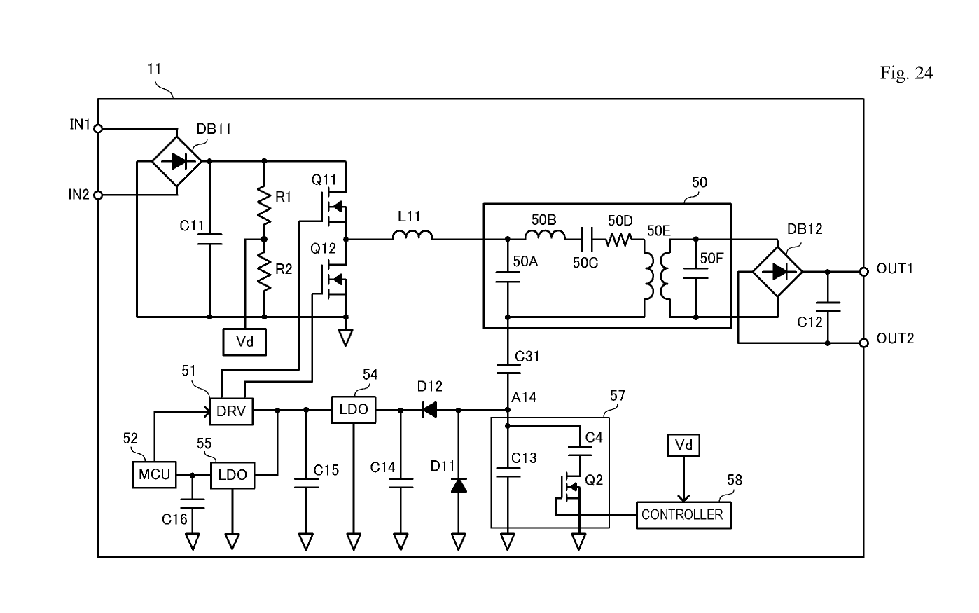

FIG. 23 is a circuit diagram of an AC adaptor 11 according to the eleventh exemplary embodiment. FIG. 24 is a circuit diagram of the AC adaptor 11 in which the piezoelectric transformer 50 illustrated in FIG. 23 is represented by an equivalent circuit. The AC adaptor 11 is an example of a “power supply circuit” according to the present disclosure.

The AC adaptor 1 includes the input units IN1 and IN2 and the output units OUT1 and OUT2. The input units IN1 and IN2 are connected to a commercial power supply. Loads are connected to the output units OUT1 and OUT2.

The diode bridge DB11 is connected to the input units IN1 and IN2. The smoothing capacitor C11 is connected to the diode bridge DB11. The diode bridge DB11 and the smoothing capacitor C11 form a rectifying and smoothing circuit. The rectifying and smoothing circuit rectifies and smooths AC voltages input from the input units IN1 and IN2. The diode bridge DB11 and the smoothing capacitor C11 are an example of an “input-side rectifying and smoothing circuit” according to the present disclosure.

A series circuit including the switching elements Q11 and Q12 is connected to the rectifying and smoothing circuit. In FIGS. 23 and 24, the switching elements Q11 and Q12 are illustrated as MOS-FETs. However, the switching elements Q11 and Q12 may be IGBTs, bipolar transistors, or the like. The voltage rectified and smoothed by the rectifying and smoothing circuit is converted into a voltage of a rectangular wave by switching of the switching elements Q11 and Q12. The series circuit including the switching elements Q11 and Q12 is an example of a “switching circuit” according to the present disclosure.

The driver (DRV) 51 is connected to gates of the switching elements Q11 and Q12. The microcomputer (MCU) 52 is connected to the driver 51. The driver 51 controls the duty ratio or switching frequencies of the switching elements Q11 and Q12. The microcomputer 52 obtains detection results of output voltages (or output currents) of the output units OUT1 and OUT2, and controls the driver 51 in accordance with comparison with a specified value.

A connection point of the switching elements Q11 and Q12 is connected to the piezoelectric transformer 50 with the inductor L11 interposed therebetween. More particularly, the piezoelectric transformer 50 includes the input electrodes E11 and E12 and the output electrodes E21 and E22. The connection point of the switching elements Q11 and Q12 is connected to the input electrode E11 of the piezoelectric transformer 50 with the inductor L11 interposed therebetween.

The input electrode E12 of the piezoelectric transformer 50 is connected to a reference potential with a capacitor C31 and the parallel circuit 57 included in an auxiliary power supply circuit described below interposed therebetween. The output electrodes E21 and E22 are connected to a rectifying and smoothing circuit including the diode bridge DB12 and the smoothing capacitor C12. The rectifying and smoothing circuit is connected to the output units OUT1 and OUT2.

The input electrodes E11 and E12 are an example of a “pair of input electrodes” according to the present disclosure. The output electrodes E21 and E22 are an example of a “pair of output electrodes” according to the present disclosure. The diode bridge DB12 and the smoothing capacitor C12 are an example of an “output-side rectifying and smoothing circuit” according to the present disclosure.

The piezoelectric transformer 50 is equivalently represented by the equivalent input capacitor 50A, the capacitor 50C, the equivalent output capacitor 50F, the inductor 50B, the resistor 50D, the ideal transformer 50E, and the like, as illustrated in FIG. 24. The inductor 50B, the capacitor 50C, and the like are parameters representing electromechanical coupling.

AC voltages are applied to the input electrodes E11 and E12 of the piezoelectric transformer 50 by the switching elements Q11 and Q12. As described above, the capacitor C13 and a parallel circuit 57 are connected to the input electrode E12. The equivalent input capacitor 50A of the piezoelectric transformer 50, the capacitor C31, the capacitor C13 of the parallel circuit 57, and the inductor L11 form a series resonance circuit. Voltage is converted into a voltage of a rectangular wave by the switching elements Q11 and Q12, and the series resonance circuit applies an AC voltage of a sine wave shape to the input electrodes E11 and E12 of the piezoelectric transformer 50. The piezoelectric transformer 50 transforms the AC voltage of the sine wave shape, and causes the resultant voltage to be output from the output electrodes E21 and E22. The voltage output from the piezoelectric transformer 50 is rectified and smoothed by the diode bridge DB12 and the smoothing capacitor C12, and is caused to be output from the output units OUT1 and OUT2. An AC voltage represents a voltage including an AC component, and also includes a pulsating voltage or the like including a DC component.

An auxiliary power supply circuit is connected to the input electrode E12 of the piezoelectric transformer 50. The auxiliary power supply circuit generates driving voltages of the driver 51 and the microcomputer 52 based on the voltage applied to the piezoelectric transformer 50, and outputs the generated driving voltages. The driving voltages of the driver 51 and the microcomputer 52 are much lower than the voltage of the commercial power supply input to the AC adaptor 11. For example, the driving voltage of the driver 51 is about 12 V. The driving voltage of the microcomputer 52 is about 3.3 V. The auxiliary power supply circuit obtains a predetermined voltage based on the voltage applied to the piezoelectric transformer 50, and generates the driving voltages of the driver 51 and the microcomputer 52.

The auxiliary power supply circuit includes the capacitors C14 and C31, the parallel circuit 57, the diodes D11 and D12, a controller 58, the voltage regulators (LDOs) 54 and 55, and the like.

The capacitor C31 and the parallel circuit 57 that are connected in series are connected in series between the input electrode E12 of the piezoelectric transformer 50 and a reference potential. In the parallel circuit 57, the capacitor C13 and a series circuit including a capacitor C4 and a switching element Q2 are connected in parallel. The switching element Q2 is turned on and off by the controller 58. When the switching element Q2 is turned on, a configuration in which the capacitor C4 is connected in parallel with the capacitor C13 is obtained. That is, the capacitance of the parallel circuit 57 varies by turning on and off the switching element Q2. Control by the controller 58 will be described later.

The parallel circuit 57 is an example of a “circuit constant variable circuit” according to the present disclosure. The capacitor C13 is an example of a “first reactance element” and a “circuit constant fixing circuit” according to the present disclosure. The controller 58 is an example of a “changing unit” according to the present disclosure.

The piezoelectric transformer 50 is a capacitive device. Therefore, the piezoelectric transformer 50, the capacitor C31, and the parallel circuit 57 form a capacitance dividing circuit. As described above, the capacitance of the parallel circuit 57 varies by turning on and off the switching element Q2. That is, the voltage dividing ratio of the capacitance dividing circuit varies by turning on and off the switching element Q2.

The capacitance of the capacitor C31 is set sufficiently larger than the composite capacitance of the equivalent input capacitor 50A and the capacitor C13. Therefore, the potential of a connection point A14 of the capacitor C31 and the parallel circuit 57 is determined mainly by the equivalent input capacitor 50A and the capacitance of the parallel circuit 57. Thus, the potential of the connection point A14 may be adjusted by the parallel circuit 57. When an auxiliary power supply circuit is connected to the input electrode E12 of the piezoelectric transformer 50, the equivalent input capacitor 50A of the piezoelectric transformer 50 is small, and therefore, the capacitor C31 may not be provided. In such a case, the auxiliary power supply circuit is connected directly to the input electrode E12 of the piezoelectric transformer 50, and a connection point of the auxiliary power supply circuit and the input electrode E12 of the piezoelectric transformer 50 is defined as the connection point A14.

The diode D11 is connected in parallel with the capacitor C13. The diode D11 is provided to extract a positive voltage from the connection point A14.

A rectifying and smoothing circuit including the diode D12 and the capacitor C14 is connected to the connection point A14. The rectifying and smoothing circuit extracts a voltage from the connection point A14 of the capacitance dividing circuit, and performs rectification and smoothing of the voltage. The voltage regulator 54, which is a series regulator, is connected to an output side of the rectifying and smoothing circuit, and the rectifying and smoothing circuit outputs the rectified and smoothed voltage to the voltage regulator 54.

The rectifying and smoothing circuit including the diode D12 and the capacitor C14 is an example of an “auxiliary-power-supply-side rectifying and smoothing circuit” according to the present disclosure. A voltage output from the rectifying and smoothing circuit is an example of an “auxiliary power supply voltage” according to the present disclosure.

The bypass capacitor C15 and the driver 51 are connected to an output side of the voltage regulator 54. The voltage regulator 54 converts the rectified and smoothed voltage at the connection point A14 into a constant voltage necessary for the driver 51. For example, when a voltage of 18 V is input to the voltage regulator 54 and the voltage necessary for driving the driver 51 is 12 V, the voltage regulator 54 steps down the voltage of 18 V to the voltage of 12 V, and outputs the stepped down voltage. Accordingly, the driver 51 operates.

Furthermore, the voltage regulator 55 is also connected to the output side of the voltage regulator 54. The bypass capacitor C16 and the microcomputer 52 are connected to an output side of the voltage regulator 55. The voltage regulator 55 steps down the voltage output from the voltage regulator 54 to a voltage necessary for driving the microcomputer 52. For example, when the voltage necessary for driving the microcomputer 52 is 3.3 V, the voltage regulator 55 steps down the voltage which has been converted into the voltage of 12 V by the voltage regulator 54 to the voltage of 3.3 V, and outputs the stepped down voltage, as described above. Accordingly, the microcomputer 52 operates.

As described above, the auxiliary power supply circuit divides, using the capacitance dividing circuit, the voltage applied to the piezoelectric transformer 50. The auxiliary power supply circuit extracts a voltage from the connection point A14 to generate the driving voltages of the driver 51 and the microcomputer 52. However, the potential of the connection point A14 varies according to the weight of loads connected to the output units OUT1 and OUT2. When the potential of the connection point A14 varies, a voltage generated by the auxiliary power supply circuit accordingly varies.

More particularly, as described above, the switching elements Q11 and Q12 are subjected to switching control by the driver 51 and the microcomputer 52 in accordance with the weight of loads. Therefore, voltages input to the switching elements Q11 and Q12 vary according to the loads. In particular, with a heavy load, there is a large swing (ripples) of the voltage at the connection point of the switching elements Q11 and Q12, which affects the potential of the connection point A14.

If the influence of the ripples causes the potential of the connection point A14 to be increased and a voltage larger than a specified value (for example, 18 V) is input to the voltage regulator 54, the voltage regulator 54 needs to step down the input voltage with a voltage difference larger than the case where voltage is stepped down from 18 V to 12 V as in the example described above. Therefore, loss in the voltage regulator 54 increases.

Thus, in order to vary the potential of the connection point A14, the capacitance of the parallel circuit 57 is varied by turning on and off the switching element Q2, and the voltage dividing ratio of the capacitance dividing circuit is thus varied. The switching element Q2 is an MOS-FET. The gate of the switching element Q2 is connected to the controller 58, and is turned on and off by the controller 58.

An input voltage detection circuit including voltage dividing resistors R1 and R2 is provided on an input side of the switching elements Q11 and Q12. An input voltage Vd detected by the input voltage detection circuit is input to the controller 58. The controller 58 compares the input voltage Vd with a predetermined reference voltage Vth. In the case where a load is heavy and the input voltage Vd is equal to or more than the reference voltage Vth, the controller 58 turns on the switching element Q2. In the case where a load is light and the input voltage Vd is less than the reference voltage Vth, the controller 58 turns off the switching element Q2.

When the switching element Q2 is turned off, the capacitance of the parallel circuit 57 is equal to the capacitance of only the capacitor C13. When the switching element Q2 is turned on, the capacitance of the parallel circuit 57 is equal to the composite capacitance of the capacitors C13 and C4 that are connected in parallel. That is, by turning on and off the switching element Q2, the voltage dividing ratio of the capacitance dividing circuit may be varied, and the potential of the connection point A14 may thus be varied.

The potential of the connection point A14 may be varied according to the input voltage Vd. Therefore, when the input voltage Vd is high, a low potential may be achieved at the connection point A14. Furthermore, when the input voltage Vd is low, a high potential may be achieved at the connection point A14. As described above, by varying the potential of the connection point A14 according to variations in the input voltage Vd, a stable voltage with less variations may be input to the voltage regulator 54.

In this embodiment, when a load is light and the input voltage Vd is less than the reference voltage Vth, that is, in the case where the switching element Q2 is turned off, constants are set for the capacitors C31 and C13 such that the voltage of the connection point A14 exceeds the driving voltage of the driver 51. That is, in the case where the switching element Q2 is turned off, a voltage necessary for driving the driver 51 may be ensured even if the voltage of the connection point A14 is low. Therefore, even with a configuration in which the control is performed when a load is heavy, no trouble occurs when the load is light.

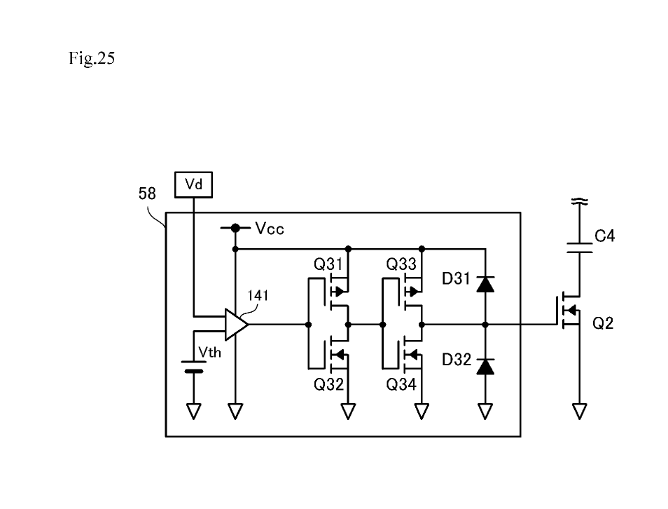

FIG. 25 is a diagram illustrating part of an internal circuit of the controller 58.

In this aspect, the controller 58 includes a comparator 141. The input voltage Vd detected by the voltage dividing resistors R1 and R2 and the reference voltage Vth are input to the comparator 141. The comparator 141 compares the input voltage Vd with the reference voltage Vth, outputs a Hi signal when Vd is equal to or more than Vth, and outputs a Lo signal when Vd is less than Vth.

Moreover, the controller 58 includes a series circuit including switching elements Q31 and Q32, a series circuit including switching elements Q33 and Q34, and a series circuit including diodes D31 and D32. These series circuits are connected in parallel between the power supply voltage Vcc and a reference potential. The switching elements Q31 and Q33 are p-type MOS-FETs. The switching elements Q32 and Q34 are n-type MOS-FETs.

Output of the comparator 141 is connected to gates of the switching elements Q31 and Q32. A connection point of the switching elements Q31 and Q32 is connected to gates of the switching elements Q33 and Q34. A connection point of the switching elements Q33 and Q34 is connected to a connection point of the diodes D31 and D32 and the gate of the switching element Q2. The diodes D31 and D32 are a protection circuit for not causing over-voltage or reverse-voltage to be input to the gate of the switching element Q2.

With this configuration, when the comparator 141 outputs a Hi signal, the switching element Q32 is turned on. Then, the switching element Q33 is turned on, a voltage is applied to the gate of the switching element Q2 from the power supply voltage Vcc, and the switching element Q2 is thus turned on. In contrast, when the comparator 141 outputs a Lo signal, that is, when the input voltage Vd is less than the reference voltage Vth, the switching element Q31 is turned on. Then, the switching element Q34 is turned on, and the switching element Q2 is thus turned off.

As described above, the controller 58 compares the input voltage Vd with the reference voltage Vth, and turns on or turns off the switching element Q2. Accordingly, the potential at the connection point A14 illustrated in FIGS. 23 and 24 may be varied so that the voltage input to the voltage regulator 54 may be stable.

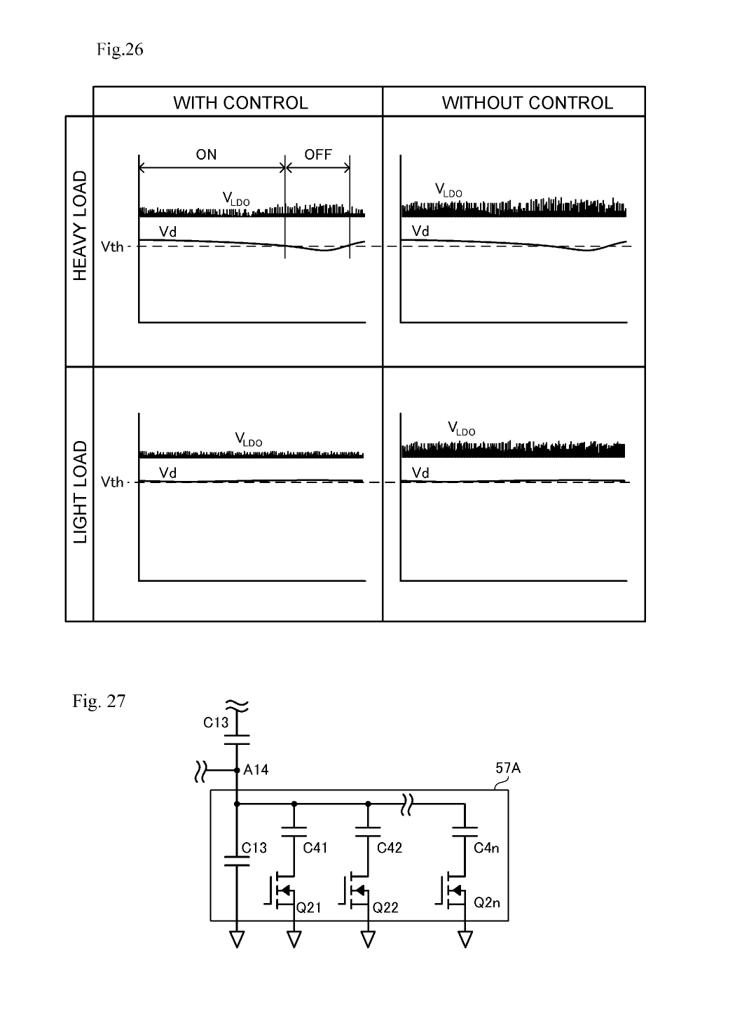

FIG. 26 is a diagram illustrating a waveform of an input voltage V_{LDO} to the voltage regulator 54. In FIG. 26, “with control” represents a case where switching control for the switching element Q2 is performed, and “without control” represents a case where a circuit including a capacitor C4 and the switching element Q2 is not provided.

The waveform of the input voltage V_{LDO} illustrated in FIG. 26 represents only ripples appearing in the input voltage V_{LDO}. Furthermore, in FIG. 26, the input voltage Vd, the reference voltage Vth, and on/off periods of the switching element Q2 are also illustrated. When there is a light load and “with control” illustrated in FIG. 26, the input voltage Vd is not equal to or more than the reference voltage Vth, the switching element Q2 is turned off.

Regardless of whether a load is heavy or light, when “with control” is compared with “without control”, smaller ripples appear in the input voltage V_{LDO} input to the voltage regulator 54 in the case of “with control”, as illustrated in FIG. 26. That is, by turning on and off the switching element Q2, ripples in the input voltage V_{LDO} input to the voltage regulator 54 may be suppressed and thus stabilized. As a result, loss in the voltage regulator 54 may be reduced.

As described above, in this embodiment, output voltage of the auxiliary power supply circuit may be stabilized, regardless of the weight of a load connected to the AC adaptor 11. Accordingly, influence of ripples appearing when a load varies may be reduced, and a situation in which the driver 51 and the like are not driven due to voltage shortage or loss in the voltage regulator 54 increases may be suppressed. Furthermore, a circuit for varying the capacitance of the parallel circuit 57 may be implemented by a simple circuit configuration including the capacitor C4 and the switching element Q2.

With a configuration in which the voltage regulators 54 and 55 are connected in cascade to generate the operating voltage of the microcomputer 52, a decrease in the efficiency of the auxiliary power supply circuit may be prevented. That is, when a voltage obtained from the connection point A14 is about 18 V and the driving voltage of the microcomputer 52 is 3.3 V, there is a large difference between the voltages. Therefore, when one voltage regulator converts the voltage of 18 V into the voltage of 3.3 V, loss in the auxiliary power supply circuit is large. Thus, by causing the voltage regulator 54 to convert the voltage of 18 V into the voltage of 12 V and then causing the voltage regulator 55 to convert the voltage of 12 V into the voltage of 3.3 V, loss in the auxiliary power supply circuit may be reduced, and efficiency may be increased.

In this embodiment, the series circuit including the capacitor C4 and the switching element Q2 is used as a circuit for varying a circuit constant (capacitance) of the parallel circuit 57. However, a configuration in which a plurality of series circuits including the capacitor C4 and the switching element Q2 are connected in parallel may be provided.

FIG. 27 is a diagram illustrating another example of a circuit for varying a circuit constant.

A parallel circuit 57A in this example has a configuration in which series circuits including capacitors C41, C42, . . . , and C4n and switching elements Q21, Q22, . . . , and Q2n, respectively, are connected in parallel with respect to the capacitor C13. In this case, the capacitance of the parallel circuit 57A may can be set in 2 n ways. Thus, the potential of the connection point A14 may be varied in a more detailed manner. Therefore, output voltage of the auxiliary power supply circuit may be stabilized with high accuracy.

In this embodiment, the input voltage detection circuit including the voltage dividing resistors R1 and R2 is provided on an input side of the switching elements Q11 and Q12 so that detection accuracy can be increased by detecting a DC voltage. However, the input voltage detection circuit may be provided at a different position. For example, the input voltage detection circuit may be provided on an input side of the voltage regulator 54 of the auxiliary power supply circuit. Furthermore, in this embodiment, the input voltage Vd is detected. However, for example, with the use of a current transformer, input current to the switching elements Q11 and Q12 may be detected. In this case, switching control for the switching element Q2 may be performed by comparing the detected input current with a reference value.

### Twelfth Embodiment

The twelfth embodiment is different from the eleventh embodiment in the position where an auxiliary power supply circuit included in an AC adaptor is provided.

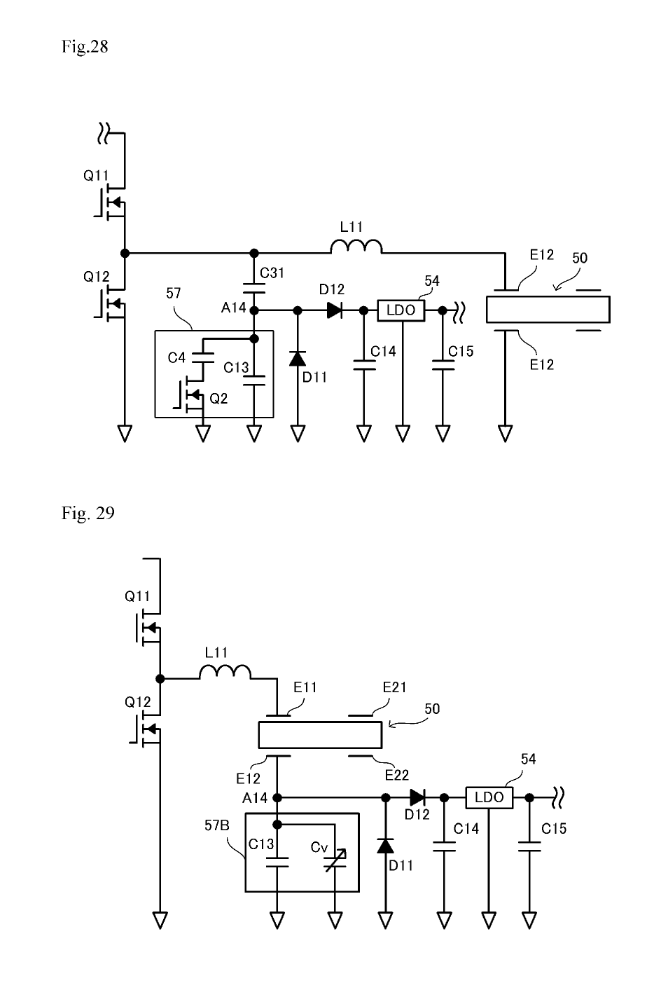

FIG. 28 is a circuit diagram illustrating an auxiliary power supply circuit included in the AC adaptor according to the twelfth embodiment. The auxiliary power supply circuit illustrated in FIG. 28 has the same configuration as that in the eleventh embodiment. Therefore, explanation will be provided by using the same signs as those in the eleventh embodiment.

In this embodiment, the capacitor C31 of the auxiliary power supply circuit is provided between the connection point of the switching elements Q11 and Q12 and the inductor L11. The input electrode E12 of the piezoelectric transformer 50 is directly connected to the reference potential. The series circuit including the capacitors C31 and C13 and the equivalent input capacitor 50A (see FIG. 2) of the piezoelectric transformer 50 are configured to be connected in parallel. The composite capacitance of this parallel circuit and the inductor L11 form a resonance circuit.

The capacitance of the capacitor C31 is set less than or equal to the capacitance of the capacitor C13. In this case, regarding the impedance of the series circuit including the capacitors C31 and C13, the capacitor C31 is predominant. Therefore, a voltage to be applied to the series circuit including the capacitors C31 and C13 is determined mainly by the capacitor C31. Furthermore, the potential of the connection point A14 may be adjusted by the parallel circuit 57.

Control by the switching element Q2 in the auxiliary power supply circuit is the same as that in the eleventh embodiment. The other configurations are the same as those in the eleventh embodiment. Therefore, explanation for the other configurations will be omitted.

As described above, even with the configuration according to this embodiment, regardless of the weight of a load connected to the AC adaptor, an output voltage of the auxiliary power supply circuit may be stabilized.

### Thirteenth Embodiment

The thirteenth embodiment is different from the eleventh embodiment in the configuration of a “circuit constant variable circuit” according to the present disclosure.

FIGS. 29, 30, and 31 are diagrams each illustrating another example of an auxiliary power supply circuit included in an AC adaptor according to the thirteenth exemplary embodiment.

As shown, the auxiliary power supply circuit illustrated in FIG. 29 includes a parallel circuit 57B in which the capacitor C13 and a variable capacitance capacitor Cv are connected in parallel. For example, electrostatic capacitance adjustment for the variable capacitance capacitor Cv is performed by the controller 58 illustrated in FIG. 23. The parallel circuit 57B is connected to the input electrode E12 of the piezoelectric transformer 50. The parallel circuit 57B is an example of a “circuit constant variable circuit” according to the present disclosure. Furthermore, the variable capacitance capacitor Cv is an example of a “variable capacitance element” according to the present disclosure.

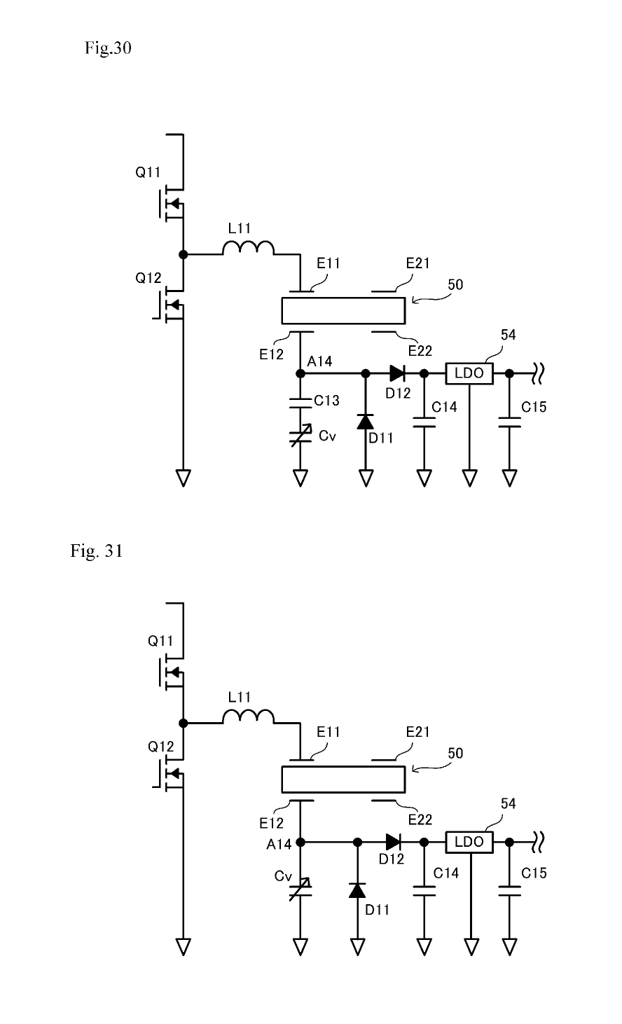

An auxiliary power supply circuit illustrated in FIG. 30 includes a series circuit including the capacitor C13 and the variable capacitance capacitor Cv. The series circuit is connected to the input electrode E12 of the piezoelectric transformer 50. The series circuit I an example of a “circuit constant variable circuit” according to the present disclosure. Furthermore, the variable capacitance capacitor Cv is an example of a “variable capacitance element” according to the present disclosure.

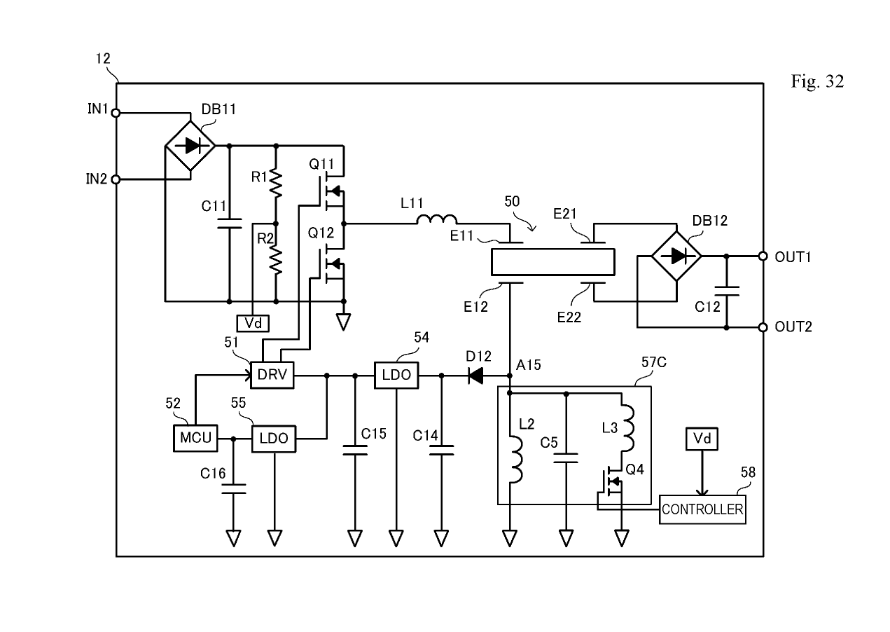

An auxiliary power supply circuit illustrated in FIG. 31 includes the variable capacitance capacitor Cv that is connected to the input electrode E12 of the piezoelectric transformer 50. In this example, the variable capacitance capacitor Cv is an example of a “first reactance element”, a “circuit constant variable circuit”, and a “variable capacitance element” according to the present disclosure.

Even in any of the cases illustrated in FIGS. 29, 30, and 31, by varying the capacitance of the variable capacitance capacitor Cv, an output voltage of an auxiliary power supply circuit may be stabilized, regardless of the weight of a load connected to an AC adaptor. Furthermore, compared to a case where the voltage dividing ratio is varied by turning on and off the switching element Q2 (see FIG. 23) as in the eleventh embodiment, high-frequency noise generated at the time of switching may be reduced.

### Fourteenth Embodiment

An AC adaptor according to a fourteenth embodiment is different from the first embodiment in the configuration of a “circuit constant variable circuit” according to the present disclosure.

FIG. 32 is a circuit diagram of an AC adaptor 12 according to a fourteenth embodiment.

An auxiliary power supply circuit of the AC adaptor 12 includes a parallel circuit 57C in which an inductor L2, a capacitor C5, and a series circuit including an inductor L3 and a switching element Q3 are connected in parallel. The parallel circuit 57C is connected to the input electrode E12 of the piezoelectric transformer 50. The switching element Q3 is turned on and off by the controller 58, as in the eleventh embodiment.

The parallel circuit 57C is an example of a “circuit constant variable circuit” according to the present disclosure. The inductor L2 is an example of a “first reactance element” according to the present disclosure. The inductor L2 and the capacitor C5 are an example of a “circuit constant fixing circuit” according to the present disclosure.

When the switching element Q3 is turned on, the inductor L3 is connected in parallel with the inductor L2. Therefore, the inductance of the parallel circuit 57C varies when the switching element Q3 is turned on and off. A constant is set such that the parallel circuit 57C becomes inductive at the switching frequencies of the switching elements Q11 and Q12. The piezoelectric transformer 50 is a capacitive device. That is, the piezoelectric transformer 50 and the parallel circuit 57C may be considered to have a configuration in which a capacitive element and an inductive element are connected in series.

Regarding the series circuit including a capacitive element and an inductive element, a voltage applied to the inductive element increases as the inductance of the inductive element increases. Therefore, by varying the impedance of the parallel circuit 57C, which is inductive, the potential of a connection point A1y of the piezoelectric transformer 50 and the parallel circuit 57C may be varied.

When the switching element Q3 is turned on and the inductor L3 is connected in parallel with the inductor L2, the impedance of the parallel circuit 57C decreases. Thus, the potential of the connection point A1y may be lowered. Therefore, even in the case where the potential of the connection point A15 is increased by the influence of ripples, the potential of the connection point A15 may be lowered by turning on the switching element Q3. In addition, a situation in which a voltage more than a specified value (for example, 18 V) is input to the voltage regulator 54 may be suppressed. As a result, loss in the voltage regulator 54 may be reduced.

As described above, even with the AC adaptor 12 having the configuration according to this embodiment, an output voltage from the auxiliary power supply circuit may be stabilized even if a load is varied, as in the eleventh to thirteenth embodiments.

### Fifteenth Embodiment

An AC adaptor according to the fifteenth embodiment is different from the fourteenth embodiment in that the inductor L3 in the parallel circuit 57C illustrated in FIG. 32 is replaced with a capacitor.

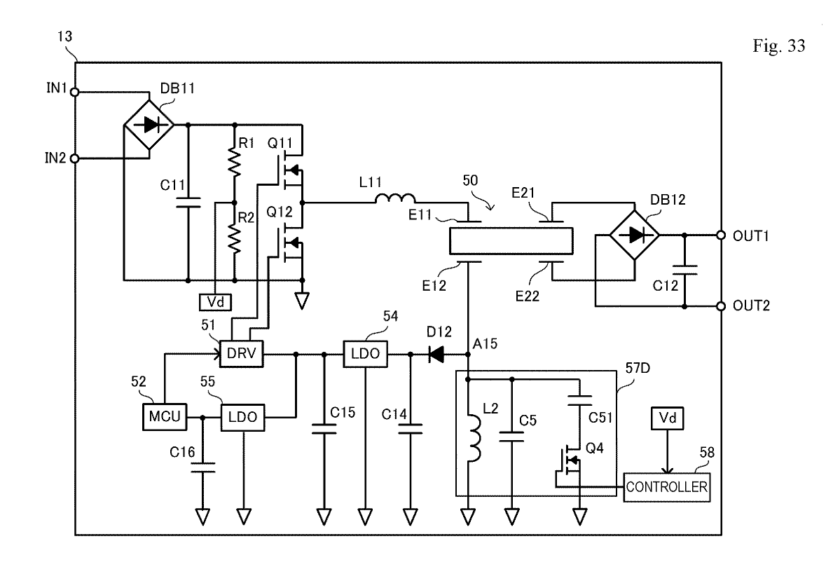

FIG. 33 is a circuit diagram of an AC adaptor 13 according to the fifteenth embodiment.

An auxiliary power supply circuit of the AC adaptor 13 incudes a parallel circuit 57D in which the inductor L2, the capacitor C5, and a series circuit including a capacitor C51 and a switching element Q4 are connected in parallel. The parallel circuit 57D is connected to the input electrode E12 of the piezoelectric transformer 50.

The parallel circuit 57D is an example of a “circuit constant variable circuit” according to the present disclosure. The inductor L2 and the capacitor C5 are an example of a “circuit constant fixing circuit” according to the present disclosure.

In this example, the controller 58 turns on the switching element Q4 when the input voltage Vd is less than the reference voltage Vth, and turns off the switching element Q4 when the input voltage Vd is equal to or more than the reference voltage Vth. By turning on the switching element Q4, a configuration in which the capacitor C51 is connected in parallel with the capacitor C5 is obtained. That is, in the case where the impedance of the parallel circuit 57D is inductive, the impedance of the parallel circuit 57D increases. Thus, the potential of the connection point A15 of the piezoelectric transformer 50 and the parallel circuit 57D may be increased.

Therefore, even in the case where the potential of the connection point A1y is increased by the influence of ripples, the potential of the connection point A1y may be lowered in the case where the impedance of the parallel circuit 57D is inductive, by turning off the switching element Q4. In addition, a situation in which a voltage more than a specified value (for example, 18 V) is input to the voltage regulator 54 may be suppressed. As a result, loss in the voltage regulator 54 may be reduced.

As described above, even with the AC adaptor 13 having the configuration according to this embodiment, an output voltage from the auxiliary power supply circuit may be stabilized even if a load is varied, as in the eleventh to fourteenth embodiments.

### REFERENCE SIGNS LIST

A1, A2, A3, A4, A5, A6, A7, A8, A9, A10, A11, A12, A13, A14, and A15: connection point, C11 and C12: smoothing capacitor, C13 and C14: capacitor, C15 and C16: bypass capacitor, C17, C18, and C19: capacitor, C2: capacitor, C20, C21, C22, C23, and C24: capacitor, C25 and C26: bypass capacitor, C27: capacitor, C31: capacitor, C4: capacitor, C41, C44, . . . , and C4n: capacitor, C5 and C51: capacitor, Cv: variable capacitance capacitor, D11 and D12: diode, D21, D22, D23, and D24: diode, D31 and D32: diode, DB11 and DB12: diode bridge, E11 and E12: input electrode, E21 and E22: output electrode, IN1 and IN2: input unit, L11, L12, L13, L14, L15, L16, L17, L18, and L19: inductor, L2: inductor, L3: inductor, OUT1 and OUT2: output unit, Q11 and Q12: switching element, Q2: switching element, Q21, Q22, . . . , and Q2n: switching element, Q3: switching element, Q31, Q32, Q33, and Q34: switching element, Q4: switching element, R1 and R2: voltage dividing resistor, 1, 2, 3, 4, 4A, 5, 6, 7, 8, 9, 10, 11, and 12: AC adaptor, 50: piezoelectric transformer, 50A: equivalent input capacitor, 50B: inductor, 50C: capacitor, 50D: resistor, 50E: ideal transformer, 50F: equivalent output capacitor, 51: driver, 52: microcomputer, 53: rectifying and smoothing circuit, 54 and 55: voltage regulator, 56, 57, 57A, 57B, 57C, and 57D: parallel circuit, 58: controller, 60, 60A, 60B, and 60C: auxiliary power supply circuit, 61 and 62: parallel circuit, 63 and 64: rectifying and smoothing circuit, 65 and 66: voltage regulator, 67 and 68: parallel circuit, and 141: comparator

1. A power supply circuit comprising:
a piezoelectric transformer that includes a pair of voltage input electrodes and a pair of voltage output electrodes;
a switching circuit connected to the pair of voltage input electrodes and configured to convert an input voltage into an AC voltage by turning on and off at least one switching element;
an output-side rectifying and smoothing circuit connected to the pair of voltage output electrodes;
a first reactance element connected between the pair of voltage input electrodes and the switching circuit; and
an auxiliary-power-supply-side rectifying and smoothing circuit connected to the first reactance element.

2. The power supply circuit according to claim 1,
wherein the first reactance element is a capacitor configured as an auxiliary power supply,
wherein the power supply circuit further comprises a diode that is connected in parallel with the capacitor configured as the auxiliary power supply, and
wherein the auxiliary-power-supply-side rectifying and smoothing circuit is connected to a parallel circuit including the capacitor and the diode.

3. The power supply circuit according to claim 2, wherein the capacitor configured as the auxiliary power supply is connected to the pair of voltage input electrodes.

4. The power supply circuit according to claim 3, wherein a capacitance of the capacitor is equal to or more than an input capacitance of the piezoelectric transformer.

5. The power supply circuit according to claim 3, wherein the capacitor configured as the auxiliary power supply is connected in parallel with the pair of voltage input electrodes.

6. The power supply circuit according to claim 5, further comprising:
an inductor connected between the pair of voltage input electrodes and the switching circuit,
wherein the capacitor configured as the auxiliary power supply is connected in parallel with a series circuit including the inductor and the pair of voltage input electrodes.

7. The power supply circuit according to claim 5, further comprising a voltage dividing capacitor connected in series with the parallel circuit.

8. The power supply circuit according to claim 7, wherein the voltage dividing capacitor has a capacitance that is less than or equal to the capacitance of the capacitor configured as the auxiliary power supply.

9. The power supply circuit according to claim 2, wherein the parallel circuit comprises a series circuit with a plurality of capacitors configured as the auxiliary power supply capacitors and connected in parallel with the diode.

10. The power supply circuit according to claim 9,
wherein the auxiliary-power-supply-side rectifying and smoothing circuit includes a plurality of auxiliary-power supply-side rectifying and smoothing circuits, and
wherein at least one of the auxiliary-power-supply-side rectifying and smoothing circuits is connected to a connection point of the plurality of auxiliary power supply capacitors.

11. The power supply circuit according to claim 10, further comprising a second reactance element that is connected in parallel with the series circuit including the plurality of auxiliary power supply capacitors.

12. The power supply circuit according to claim 1, further comprising:
an inductive circuit that includes the first reactance element and becomes inductive at a switching frequency of the switching circuit,
wherein the auxiliary-power-supply-side rectifying and smoothing circuit is connected to the inductive circuit.

13. The power supply circuit according to claim 12,
wherein the first reactance element is an inductor, and
wherein the inductor and a capacitor of the inductive circuit are connected in parallel.

14. The power supply circuit according to claim 12, wherein the inductive circuit includes a series connection unit having a plurality of inductors connected in series.

15. The power supply circuit according to claim 14,
wherein the auxiliary-power-supply-side rectifying and smoothing circuit includes a plurality of auxiliary-power supply-side rectifying and smoothing circuits, and
wherein at least one of the plurality of auxiliary-power-supply-side rectifying and smoothing circuits is connected to a connection point of two of the plurality of inductors of the inductive circuit.

16. The power supply circuit according to claim 14, further comprising a capacitor that is connected in parallel with the series connection unit.

17. The power supply circuit according to claim 14, further comprising an inductor connected in parallel with the series connection unit.

18. The power supply circuit according to claim 12,
wherein the first reactance element is an inductor,
wherein the inductive circuit comprises another inductor connected in parallel with the inductor and a capacitor connected in series,
wherein the auxiliary-power-supply-side rectifying and smoothing circuit includes a plurality of auxiliary-power supply-side rectifying and smoothing circuits, and
wherein at least one of the plurality of auxiliary-power-supply-side rectifying and smoothing circuits is connected to a connection point of the capacitor and the inductor that are connected in series.

19. The power supply circuit according to claim 1, wherein the first reactance element and the switching circuit are connected via ground.

20. The power supply circuit according to claim 1, further comprising a voltage regulator connected to the auxiliary-power-supply-side rectifying and smoothing circuit.

21. The power supply circuit according to claim 20, further comprising a driver circuit connected to the voltage regulator and configured to drive the switching element.

22. The power supply circuit according to claim 20, further comprising a controller connected to the voltage regulator and configured to control the switching element to turn on and off the at least one switching element.

23. The power supply circuit according to claim 1, further comprising:
a detection circuit configured to detect a value based on an input current or input voltage input to the piezoelectric transformer;
a circuit constant variable circuit connected to the pair of input electrodes or connected between the pair of input electrodes and the switching circuit and configured change a circuit constant; and
a controller configured to change the circuit constant based on the value detected by the detection circuit,
wherein the circuit constant variable circuit includes the first reactance element, and
wherein the auxiliary-power-supply-side rectifying and smoothing circuit rectifies and smooths a voltage applied to the circuit constant variable circuit and outputs an auxiliary power supply voltage.

24. The power supply circuit according to claim 23, wherein the circuit constant variable circuit includes a circuit constant fixing circuit.

25. The power supply circuit according to claim 23,
wherein the circuit constant variable circuit includes a switching element, and
wherein the controller is configured to change the circuit constant of the circuit constant variable circuit by turning on and turning off the switching element of the circuit constant variable circuit.

26. The power supply circuit according to claim 23, wherein the circuit constant variable circuit includes a variable capacitance element.

27. The power supply circuit according to claim 23, wherein the detection circuit is connected to an input side of the switching circuit.

28. An AC adaptor comprising:
an input that is configured to connect to a commercial power supply and to input a voltage received from the commercial power supply;
an input-side rectifying and smoothing circuit configured to rectify and smooth the voltage from the input;
a piezoelectric transformer that includes a pair of voltage input electrodes and a pair of voltage output electrodes;
a switching circuit connected to the pair of voltage input electrodes and configured to convert the voltage rectified and smoothed by the input-side rectifying and smoothing circuit by turning on and turning off at least one switching element;
an output-side rectifying and smoothing circuit connected to the pair of voltage output electrodes;
an output configured to output the voltage rectified and smoothed by the output-side rectifying and smoothing circuit;
a reactance element connected between the pair of voltage input electrodes and the switching circuit; and
an auxiliary-power-supply-side rectifying and smoothing circuit connected to the reactance element.
